(19) United States
(12) Patent Application Publication
(10) Pub. No.: US 2009/0258470 A1
(43) Pub. Date: Oct. 15, 2009

(54) Method of Manufacturing a Semiconductor Device Using an Atomic Layer Deposition Process

(75) Inventors: Jae-Hyoung Choi, Gyeonggi-do (KR); Jin-Hyuk Choi, Gyeonggi-do (KR); Cha-Young Yoo, Gyeonggi-do (KR); Kyu-Ho Cho, Gyeonggi-do (KR); Wan-Don Kim, Gyeonggi-do (KR); Kyoung-Ryul Yoon, Gyeonggi-do (KR); Jae-Hyun Yeo, Gyeonggi-do (KR); Yong-Suk Tak, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/423,249

(22) Filed: Apr. 14, 2009

(30) Foreign Application Priority Data
Apr. 14, 2008 (KR) 2008-33997

(51) Int. Cl. H01L 21/02; H01L 21/28; H01L 21/31

(52) U.S. Cl. 438/386; 438/593; 438/768; 257/E21.008; 257/E21.209; 257/E21.24

(57) ABSTRACT

Methods of manufacturing a semiconductor device include forming an absorption layer on a surface of a substrate by exposing the surface of the substrate to a first reaction gas at a first temperature. A metal oxide layer is then formed on the surface of the substrate by exposing the absorption layer to a second reaction gas at a second temperature. The first reaction gas may include a precursor containing zirconium (e.g., tetrakis(ethylmethylamino)zirconium) and the second reaction gas may include an oxidizing agent.

### REFERENCE TO PRIORITY APPLICATION

This application claims priority from Korean Patent Application No. 2008-0033997, filed Apr. 14, 2008, the disclosure of which is hereby incorporated herein by reference.

### FIELD OF THE INVENTION

Example embodiments relate to a semiconductor device and a method of manufacturing a semiconductor device. More particularly, example embodiments relate to a semiconductor device having desired step coverage and electric characteristics through an atomic layer deposition (ALD) process, and a method of manufacturing the semiconductor device.

### BACKGROUND

Semiconductor devices have considerably reduced sizes of unit cells as the semiconductor devices are highly integrated to meet the high capacity of various electronic apparatuses. Hence, patterns in the semiconductor devices also have greatly decreased dimensions and intervals between adjacent patterns. Although the unit cell of the semiconductor device has a minute size, the semiconductor should have more improved electrical characteristics for recent various electronic apparatuses. Therefore, new materials and structures have been developed for the highly integrated semiconductor device having enhanced electrical characteristics.

Recently, a high-k dielectric layer has been used in the semiconductor device so as to improve a storage capacitance of a capacitor, a coupling ratio of a flash memory device, a threshold voltage of a transistor, etc. For example, a zirconium oxide layer is used as a dielectric layer, a tunnel oxide layer or a gate insulation layer in the semiconductor device. However, the zirconium oxide layer may not be uniformly formed at a desired portion of the semiconductor device when the semiconductor device has minute patterns. Particularly, the zirconium oxide layer may not be conformally formed on an inside and a bottom of a cylindrical electrode or pattern in the semiconductor device when the zirconium oxide layer is formed by a conventional ALD process. That is, the zirconium oxide layer may not be uniformly formed on a structure having a high aspect ratio because of the poor step coverage of the zirconium oxide layer formed by the conventional ALD process. Further, the zirconium oxide layer obtained by the conventional ALD process may not ensure sufficient leakage current characteristics even though the zirconium oxide layer has proper step coverage by the conventional ALD process.

### SUMMARY

Example embodiments provide a semiconductor device including a zirconium compound layer having good step coverage and leakage current characteristics by varying the process temperature in an ALD process.

Example embodiments provide a method of manufacturing a semiconductor device including zirconium compound layer that ensures good step coverage and leakage current characteristics by varying the process temperature in an ALD process.

Example embodiments provide a zirconium compound layer ensuring good step coverage and leakage current characteristics by varying the process temperature in an ALD process.

Example embodiments provide a zirconium compound layer ensuring good step coverage and leakage current characteristics by varying the process temperature in an ALD process.

Example embodiments provide a method of manufacturing a semiconductor device including a zirconium compound layer having good step coverage and leakage current characteristics by varying the process temperature in an ALD process.

Example embodiments provide an apparatus for performing an ALD process to produce a zirconium compound layer having good step coverage and leakage current characteristics by varying the process temperature in the ALD process.

According to one aspect of example embodiments, there is provided a method of manufacturing a semiconductor device. In the method of manufacturing the semiconductor device, a substrate is loaded into a reaction chamber. An absorption layer is formed on the substrate by providing a first reaction gas onto the substrate at a first temperature. A remaining first reaction gas is purged from the substrate. A metal oxide layer is formed on the substrate by providing a second reaction gas onto the absorption layer at a second temperature. A remaining second reaction gas is purged from the substrate.

In example embodiments, the first reaction gas may include a precursor including zirconium and the second reaction gas comprises an oxidizing agent. Here, the precursor may include tetrakis ethylmethylamino zirconium [Zr(N(C₂H₅))₄; TEMAZ] and the oxidizing agent may include an oxygen gas, an ozone gas and/or a water vapor.

In example embodiments, the second temperature may be substantially higher than the first temperature. For example, the first temperature may be in a range of about 240° C. to about 260° C., and the second temperature may be in a range of about 265° C. to about 285° C.

In example embodiments, a metal oxynitride layer may be additionally formed on the substrate by providing a third reaction gas onto the metal oxide layer. The metal oxynitride layer may be treated with a plasma. A remaining third reaction gas may be purged from the substrate.

In example embodiments, the third reaction gas may include a nitrifying agent and the plasma may include nitrogen. Here, the third reaction gas may include at least one of nitrogen monoxide, nitrogen dioxide and ammonia (NH₃).

In example embodiments, a cylindrical lower electrode may be additionally formed between the substrate and the metal oxide layer. An upper electrode may be formed on the metal oxide layer.

In example embodiments, an insulation layer may be further formed between the substrate and the metal oxide film. A floating gate having a U shape may be formed on the insulation layer, and a control gate may be formed on the metal oxide layer.

According to another aspect of example embodiments, there is provided a method of manufacturing a semiconductor device. In the method of manufacturing a semiconductor device, a substrate is loaded into a reaction chamber. An absorption layer is formed on the substrate by providing a first reaction gas onto the substrate at a first temperature. A remaining first reaction gas is purged from the substrate. A metal oxide layer is formed on the substrate by providing a second reaction gas onto the absorption layer at a second temperature. A remaining second reaction gas is purged from the substrate. A metal oxynitride layer is formed on the substrate by providing a third reaction gas onto the metal oxide layer. A remaining third reaction gas is purged from the reaction chamber. A dielectric structure is formed by alternately repeating forming the metal oxide layer and forming the metal oxynitride layer.

In example embodiments, the first temperature may be in a range of about 240° C. to about 260° C., and the second temperature may be in a range of about 265° C. to about 285° C.

According to still another aspect of example embodiments, there is provided a semiconductor device including a substrate, a zirconium compound layer formed on the substrate and an electrode formed on the zirconium compound layer. The zirconium compound layer is obtained by varying a process temperature in an ALD process.

In example embodiments, the zirconium compound layer may have at least one zirconium oxide layer and at least one zirconium oxynitride layer.

In example embodiments, the zirconium compound layer may be formed while increasing the process temperature from a first temperature to a second temperature higher than the first temperature.

In example embodiments, a lower electrode may be additionally disposed between the substrate and the zirconium compound layer.

According to still another aspect of the example embodiments, there is provided an apparatus for performing an ALD process. The apparatus includes a reaction chamber, a substrate holder disposed in the reaction chamber, a gas supply line extending over the substrate holder, a heating block changing temperatures of the sections of the substrate holder; and a controller for controlling process conditions in the ALD process such as reaction gases, purging gases, a rotation speed of the substrate holder, the temperatures of the sections of the substrate holder, etc. The substrate holder has a plurality of sections on which a plurality of substrates is loaded.

In example embodiments, the heating block may include at least one of a UV lamp, a halogen lamp and a heater.

In example embodiments, the sections of the substrate holder may be separated by separation walls or air curtains.

In example embodiments, the gas supply line may have a circular structure including a plurality of nozzles to provide different reaction gases and purging gases onto the sections of the substrate holder.

According to example embodiments, the zirconium compound layer may be obtained by varying the process temperature in the ALD process, so that the zirconium compound layer may have good step coverage and improved leakage current characteristics. When the zirconium compound layer is employed in a semiconductor device as a dielectric layer, a gate insulation layer or a tunnel insulation layer, the zirconium compound layer may be uniformed formed on a predetermined structure even though the predetermined structure has high aspect ratio. For example, the zirconium compound layer may be conformally formed on a cylindrical lower electrode of a capacitor, a floating gate having a U shape, a sidewall of a vertical transistor having an I shape, etc. Further, the semiconductor device including the zirconium compound layer may ensure improved reliability the electrical characteristics.

Meanwhile, the apparatus for performing the ALD process includes the substrate holder and the heating block, a plurality of zirconium compound layers may be simultaneously provided on a plurality of substrates. Thus, the yield of manufacturing semiconductor devices may be considerably improved.

### BRIEF DESCRIPTION OF THE DRAWINGS

Example embodiments can be understood in more detail from the following description taken in conjunction with the accompanying drawings, in which:

FIG. 1 is a graph illustrating a deposition rate of a zirconium oxide layer relative to a deposition temperature in accordance with example embodiments;

FIG. 2 is a graph illustrating a step coverage of a zirconium oxide layer formed on a cylindrical lower electrode relative to a temperature in accordance with example embodiments;

FIG. 3 is a graph illustrating a variation of leakage currents of a capacitor including zirconium oxide layer relative to an equivalent oxide thickness of the zirconium oxide layer in accordance with example embodiments;

FIG. 4 is a timing sheet illustrating a conventional method of forming a zirconium oxide layer;

FIG. 5 is a timing sheet illustrating a method of forming a zirconium oxide layer in accordance with example embodiments;

FIG. 6 is a timing sheet illustrating a method of forming a zirconium oxynitride layer in accordance with example embodiments;

FIG. 7 is a plan view illustrating an apparatus for performing an ALD process in accordance with example embodiments;

FIGS. 8 to 23 are cross sectional views illustrating a method of manufacturing a semiconductor device in accordance with example embodiments;

FIGS. 24 to 34 are cross sectional views illustrating a method of manufacturing a semiconductor device in accordance example embodiments;

FIG. 35 is a cross sectional view illustrating a method of manufacturing a semiconductor device in accordance other example embodiments;

FIG. 36 is a cross sectional view illustrating a method of manufacturing a semiconductor device in accordance other example embodiments;

FIGS. 37 to 47 are cross sectional views illustrating a method of manufacturing a semiconductor device in accordance with example embodiments;

FIGS. 48 to 61 are cross-sectional views illustrating a method of manufacturing a semiconductor device in accordance with example embodiments;

FIG. 62 is a block diagram illustrating a memory system in accordance with example embodiments;

FIG. 63 is a block diagram illustrating another memory system in accordance with example embodiments; and

FIG. 64 is a block diagram illustrating still another memory system in accordance with example embodiments.

### DESCRIPTION OF EMBODIMENTS

The example embodiments are described more fully hereinafter with reference to the accompanying drawings. The invention may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments (and intermediate structures) of the invention. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Methods of Forming a Zirconium Oxide Layer and a Zirconium Oxynitride Layer

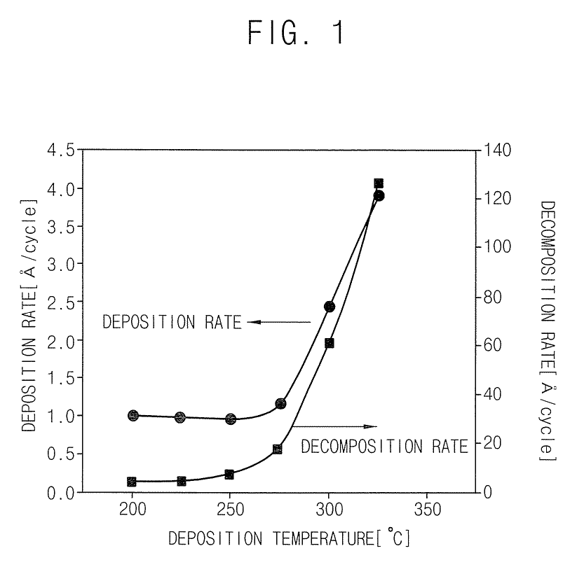

FIG. 1 is a graph illustrating a deposition rate of a zirconium oxide layer relative to a deposition temperature of an ALD process in accordance with example embodiments. In FIG. 1, “•” indicates the deposition rate of the zirconium oxide layer, and “▪” denotes a decomposition rate of the zirconium oxide layer.

As illustrated in FIG. 1, the deposition and the decomposition rates of the zirconium oxide layer may be substantially constant at a temperature below about 275° C. when the zirconium oxide layer is formed on an object by the atomic layer deposition (ALD) process in a reaction chamber. However, the deposition and the decomposition rates of the zirconium oxide layer may be abruptly increased at a temperature above about 275° C. Here, the object may include a substrate, an insulation layer, a conductive layer, etc. For example, the object may include a semiconductor substrate, a silicon-on-insulator (SOI) substrate, a germanium-on-insulator (GOI) substrate, an oxide layer, a nitride layer, an oxynitride layer, a metal layer, a polysilicon layer, a metal compound layer, etc.

As for the formation of the zirconium oxide layer on the object, the ALD process may be dominated at the temperature below about 275° C. whereas a chemical vapor deposition (CVD) process may be dominated at the temperature above about 275° C. although the zirconium oxide layer is formed on the object by the ALD process. In other world, the deposition mechanism of the zirconium oxide layer may vary by the process temperature while forming the zirconium oxide layer. Therefore, the zirconium oxide layer may be obtained by the ALD process only without the influence of the CVD process when the zirconium oxide layer is formed at the temperature below about 275° C.

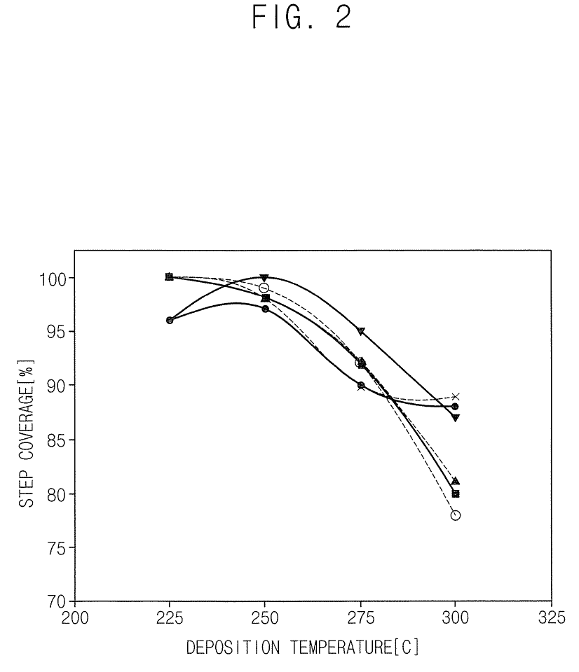

FIG. 2 is a graph illustrating step coverage of a zirconium oxide layer formed on a cylindrical lower electrode relative to a temperature in accordance with example embodiments. The zirconium oxide layer may serve as a dielectric layer of a capacitor having the cylindrical lower electrode in a capacitor.

In FIG. 2, “x” denotes the step coverage of the zirconium oxide layer at an outer upper portion of the cylindrical lower electrode, and “•” represents the step coverage of the zirconium oxide layer at an inner central portion of the cylindrical lower electrode. Additionally, “▾” indicates the step coverage of the zirconium oxide layer at an inner upper portion of the cylindrical lower electrode, and “▴” means the step coverage of the zirconium oxide layer at an outer central portion of the cylindrical lower electrode. Furthermore, “▪” indicates the step coverage of the zirconium oxide layer at an inner lower portion of the cylindrical lower electrode, and “∘” represents the step coverage of the zirconium oxide layer at an outer lower portion of the cylindrical lower electrode.

Referring to FIG. 2, the step coverage of the zirconium oxide layer with respect to the positions of the lower electrode may be maintained when the zirconium oxide layer is formed at a temperature below about 250° C. That is, the step coverage of the zirconium oxide layer may be substantially similar at the entire outer and the entire inner portions of the lower electrode. However, the step coverage of the zirconium oxide layer may vary when the zirconium oxide layer is formed at a temperature above about 250° C. Particularly, the step coverage of the zirconium oxide layer may be considerably different between the upper portion of the lower electrode and the lower portions of the lower electrode as the deposition temperature of the zirconium oxide layer is increased.

The step coverage difference of the zirconium oxide layer may increase according as the cylindrical lower electrode has relatively high aspect ratio. This step coverage different of the zirconium oxide layer may be generated because the zirconium oxide layer at the upper portions of the lower electrode may be relatively thicker than the zirconium oxide layer at the lower portions of the lower electrode when the zirconium oxide layer is formed at the temperature above about 250° C. Namely, the zirconium oxide layer may not be properly formed at the lower portions of the lower electrode as cycles of the ALD process proceed when the deposition temperature of the zirconium oxide layer is relatively high.

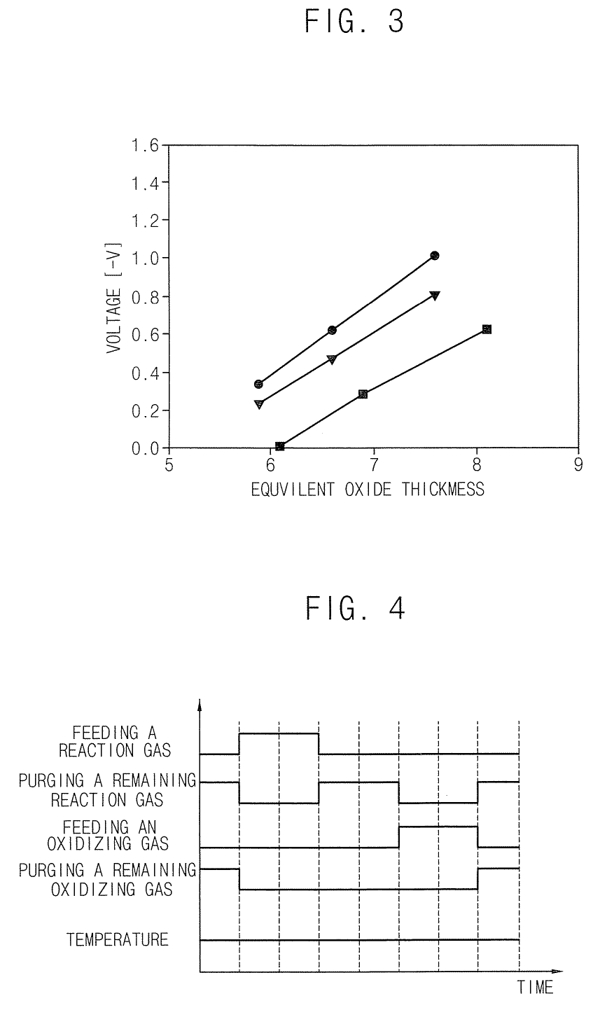

FIG. 3 is a graph illustrating a variation of leakage currents of a capacitor including zirconium oxide layer relative to an equivalent oxide thickness of the zirconium oxide layer in accordance with example embodiments. In FIG. 3, “•” represents the variation of the leakage current of the capacitor having the zirconium oxide layer obtained at a temperature of about 275° C., and “▾” denotes the variation of the leakage current of the capacitor having the zirconium oxide layer obtained at a temperature of about 265° C. Further, “•” indicates the variation of the leakage current of the capacitor having the zirconium oxide layer obtained at a temperature of about 250° C.

As illustrated in FIG. 3, the variation of the leakage current of the capacitor relative to the equivalent oxide thickness of the zirconium oxide layer may be improved as the deposition temperature of the zirconium oxide layer is increased. That is, the leakage current characteristics of the capacitor including a zirconium oxide layer may be enhanced when the zirconium oxide layer is obtained at a relatively high temperature.

Referring to FIGS. 2 and 3, the zirconium oxide layer may have good step coverage when the zirconium oxide layer is formed at a relatively low process temperature, whereas the leakage current characteristics of the capacitor having the zirconium oxide layer may be improved when the zirconium oxide layer is obtained at a relatively high process temperature. To identify the characteristics of the zirconium oxide layer depending on a deposition temperature, the zirconium oxide layer is analyzed using an X-ray photo-electro spectroscopy.

The following Table shows concentrations of ingredients in the zirconium oxide layer with respect to the deposition temperature of the zirconium oxide layer. Here, the zirconium oxide layer having a thickness of about 120 Å is formed on a titanium nitride layer having a thickness of about 250 Å.

TABLE

| | |
|---|---|
| Deposition | Concentrations [Atomic %] |

| Temperature | Zr | C | O | F |
|---|---|---|---|---|
| 250° | 28.0% | 20.6% | 50.2% | 1.2% |
| 275° | 28.4% | 19.7% | 50.6% | 1.3% |
| 300° | 27.8% | 22.8% | 48.4% | 1.1% |

As shown in the Table, the concentrations of carbon in the zirconium oxide layers obtained at temperatures of about 250° C. and about 300° C. are higher than the concentration of carbon in the zirconium oxide layer formed at a temperature of about 275° C. However, the concentration of zirconium, oxygen and fluorine in the zirconium oxide layer formed at a temperature of about 275° C. higher than the concentrations of zirconium, oxygen and fluorine in the zirconium oxide layers obtained at the temperatures of about 250° C. and about 300° C.

When the zirconium oxide layer is formed by the ALD process at the process temperature of about 250° C., the concentration of carbon in the zirconium oxide layer is relatively high because carbon in a precursor may not properly oxidized in the ALD process. However, the concentration of carbon in the zirconium oxide layer is relatively low since carbon in the precursor may be desirably oxidized in the ALD process when the zirconium oxide layer is formed at the process temperature of about 275° C. Further, the concentration of carbon in the zirconium oxide layer is also relatively high when the zirconium oxide layer is formed at the temperature of about 300° C. because the zirconium oxide layer is formed through a CVD process rather than the ALD process. When the concentration of carbon in the zirconium oxide layer is increased, the concentration of oxygen in the zirconium oxide layer may be reduced because of the reaction between carbon and oxygen.

As described above, when the zirconium oxide layer is formed by the ALD process at a relatively low deposition temperature such as about 250° C., the zirconium oxide layer may have desired step coverage whereas the leakage current characteristics of the zirconium oxide layer may be deteriorated. When the zirconium oxide layer is formed by the ALD process at a relatively high deposition temperature such as about 275° C., the zirconium oxide layer may have good leakage current characteristics whereas the zirconium oxide layer may have poor step coverage.

As a semiconductor device has a minute design rule, a capacitor including a dielectric layer may have high aspect ratio. Thus, to improve electrical characteristics of the semiconductor device having the capacitor, the step coverage of the zirconium oxide layer serving the dielectric layer may be an important factor rather than the leakage current characteristics of the zirconium oxide layer. Considering the above-mentioned problems, example embodiments provide a method of forming a zirconium oxide layer having good step coverage and desired leakage current characteristics by varying the process temperature in the ALD process.

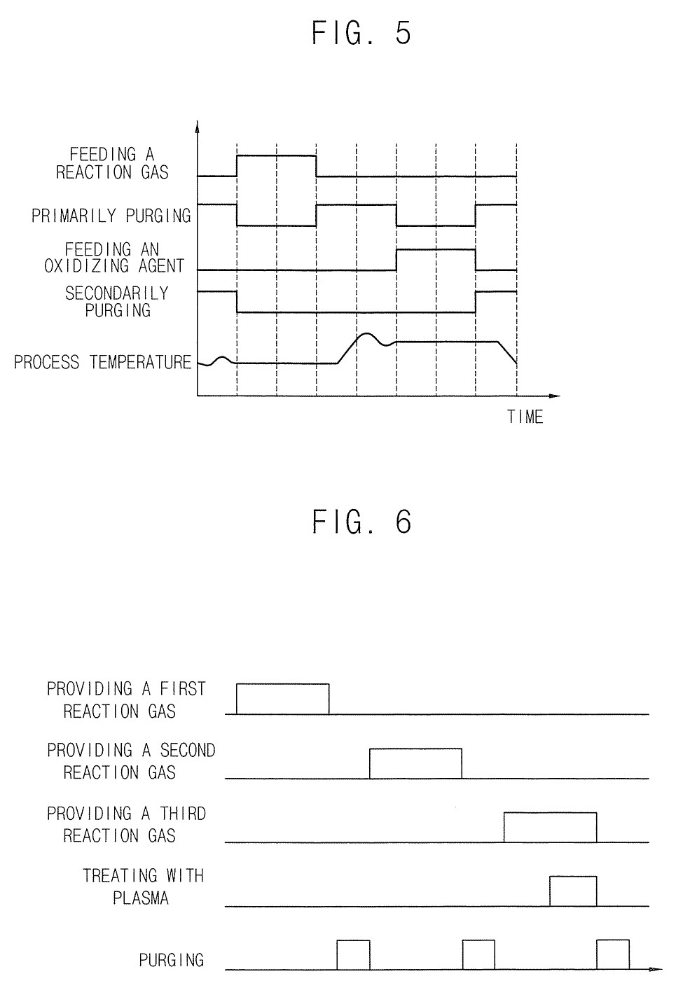

FIG. 4 is a timing sheet illustrating a conventional method of forming a zirconium oxide layer. FIG. 5 is a timing sheet illustrating a method of forming a zirconium oxide layer in accordance with example embodiments.

Referring to FIG. 4, the zirconium oxide layer is formed without the variation of the deposition temperature. In the conventional ALD process, the zirconium oxide layer is formed by performing the cycles of feeding a reaction gas into a reaction chamber, purging a remaining reaction gas from the reaction chamber, feeding an oxidizing gas into the reaction chamber, and purging a remaining oxidizing gas from the reaction chamber. However, the deposition temperature of the zirconium oxide layer is constantly maintained during the conventional ALD process.

When the zirconium oxide layer is formed at a temperature above about 270° C., the zirconium oxide layer may have poor step coverage although the zirconium oxide layer may have good density. When the zirconium oxide layer is obtained at a temperature below about 250° C., the zirconium oxide layer may have deteriorated leakage current characteristics even though the zirconium oxide layer may ensure good step coverage.

As illustrated in FIG. 5, a process temperature of an ALD process may vary while forming a zirconium oxide layer on an object in accordance with example embodiments. According to example embodiments, the zirconium oxide layer may be obtained by repeatedly performing the cycle of feeding a reaction gas including a precursor onto the object loaded in a reaction chamber, primarily purging the reaction chamber to remove an reacted reaction gas, feeding an oxidizing agent onto the object in the reaction chamber, and secondarily purging the reaction chamber to removed an unreacted oxidizing agent. Here, the reaction gas may be provided onto the object while maintaining the object with a first temperature, and the oxidizing agent may be introduced into the reaction chamber while maintaining the object with a second temperature substantially higher than the first temperature. That is, the reaction chamber may have the second temperature while secondarily purging the reaction chamber before feeding the oxidizing agent into the reaction chamber. Further, the process temperature in the ALD process may be reduced while secondarily purging a remaining oxidizing agent from the reaction chamber after feeding the oxidizing agent.

In example embodiments, the reaction gas including the precursor containing zirconium may be provided on the object after loading the object into the reaction chamber at the first temperature, so that an absorption film containing zirconium may be formed on the object. The first temperature may be in a relatively low range of about 240° C. to about 260° C. For example, the reaction gas including the precursor may be introduced into the reaction chamber at the first temperature of about 250° C. A first purge step may be executed to remove a remaining reaction gas from the reaction chamber after forming the absorption film on the object. For example, the reaction chamber may be primarily purged using a first purge gas such as an inactive gas.

While primarily purging the reaction chamber, the process temperature in the ALD process may be increased to the second temperature from the first temperature. The second temperature may be in a relatively high range of about 265° C. to about 285° C. The oxidizing agent may be introduced onto the object having the absorption film at the second temperature, such that a metal oxide layer may be formed on the object. For example, the oxidizing agent may be provided at the second temperature of about 275° C. A second purge step may be carried out to remove a remaining oxidizing agent from the reaction chamber. Namely, the reaction chamber may be secondarily purged using a second purge gas like an inactive gas. While performing the second purge step, the process temperature in the ALD process may be reduced. Alternatively, the process temperature of the ALD process may be reduced after completing the second purge step. For example, the process temperature may be decreased from the second temperature to the first temperature. When the above-described steps of the ALD process may be repeatedly executed, the zirconium oxide layer having desired thickness may be obtained on the object.

In the method of forming the zirconium oxide layer, the precursor may include tetrakis ethylmethyl amino zirconium [Zr(N(C₂H₅)₂)₄); TEMAZ] represented as the following chemical formula:

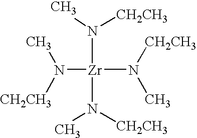

When the zirconium oxide layer may serve as a gate insulation layer or a tunnel insulation layer in a semiconductor memory device, the reaction gas including the precursor may be provided on a substrate such as a semiconductor substrate or a substrate including a semiconductor layer. For example, the substrate may include a silicon substrate, a germanium substrate, a silicon-germanium substrate, a silicon-on-insulator (SOI) substrate, a germanium-on-insulator (GOI) substrate, etc. When the zirconium oxide layer may serve as a dielectric layer in a capacitor or a flash memory device, the reaction gas may be introduced onto a conductive layer such as a lower electrode of the capacitor or a floating gate of the flash memory device. For example, the conductive layer or the floating gate may include polysilicon, metal and/or metal compound.

After the reaction gas including the precursor onto the substrate or the conductive layer in the reaction chamber at the first temperature, the absorption film may be formed on the substrate or the conductive layer. That is, a portion of the precursor may be chemically absorbed (i.e., chemisorbed) on the substrate or the conductive layer, so that the absorption film may be obtained on the substrate or the conductive layer. The reaction chamber may be primarily purged using the first purge gas. For example, the first purge gas may include an argon (Ar) gas, a helium (He) gas, a xenon (Xe) gas, a nitrogen (N₂) gas, etc. These may be used alone or in a mixture thereof. In the first purge step, a remaining reaction gas may be removed from the reaction chamber. For example, a physically absorbed (i.e., physorbed) portion and a drifting portion of the reaction gas may be removed from the substrate or the conductive layer by primarily purging the reaction chamber. While performing the first purge step, the process temperature may be changed from the first temperature to the second temperature. In other words, the reaction chamber may have the second temperature in the first purge step. Alternatively, the substrate or the conductive layer may have the second temperature after completing the first purge step. The processes temperature may be increased using a lamp or a heater. For example, the reaction chamber may have the second temperature using a halogen lamp, an ultraviolet (UV) ray lamp, an electrical heater, etc. These may be used alone or in a combination thereof.

The oxidizing agent may be provided onto the absorption film on the substrate or the conductive layer while maintaining the reaction chamber with the second temperature. The oxidizing agent may be reacted with the absorption film to form a zirconium oxide layer on the substrate or the conductive layer. For example, the oxidizing agent may include an oxygen (O₂) gas, an ozone (O₃) gas, a water (H₂O) vapor, etc. These may be used alone or in a mixture thereof. When the oxidizing agent includes the ozone gas having relatively high oxidizing power, carbon and/or nitrogen included in the absorption film may be oxidized to obtain a desired pure zirconium oxide layer.

The second purge step may be performed about the reaction chamber using the second purge gas to remove a remaining oxidizing agent from the substrate or the conductive layer. The second purge gas may include a helium gas, an argon gas, a xenon gas, a nitrogen gas, etc. These may be used alone or in a mixture thereof. While secondarily purging the reaction chamber, the process temperature in the ALD process may be reduced from the second temperature to the first temperature. For example, the reaction chamber may have the first temperature by providing a cooling gas such as an inactive gas having a relatively low temperature into the reaction chamber. For example, the cooling gas may have a temperature substantially the same as or substantially similar to the first temperature. Alternatively, the cooling gas may have a temperature substantially larger or smaller than the first temperature.

After repeatedly performing the cycle including providing the reaction gas, the first purge step, providing the oxidizing agent and the second purge step, the zirconium oxide layer having the desired thickness may be formed on the substrate or the conductive layer. For example, the zirconium oxide lay have a thickness of about 30 Å to about 50 Å by repeating the cycle of the ALD process about 40 times to about 50 times. However, the thickness of the zirconium oxide layer may vary by the number of the cycle of the ALD process.

According to example embodiments, the zirconium oxide may be obtained by varying the process temperature in the ALD process, so that the zirconium oxide layer may have good step coverage and improved leakage current characteristics.

In some example embodiments, other metal oxide layer may be formed on an object by an ALD process substantially similar to the above-described ALD process. For example, an aluminum oxide layer, a tantalum oxide layer or a titanium oxide layer having good step coverage and desired leakage current characteristics may be obtained by varying the process temperature in the ALD process. Further, a metal oxide layer, which includes at least one of the zirconium oxide layer, the aluminum oxide layer, the tantalum oxide layer and the titanium oxide layer, may be provided on an object through ALD processes substantially similar to the above-described ALD process.

FIG. 6 is a timing sheet illustrating a method of forming a zirconium oxynitride layer in accordance with example embodiments.

Referring to FIG. 6, a first reaction gas may be provided onto an object to form an absorption film on the object after loading the object into a reaction chamber where an ALD process is carried out. The object may include a substrate, a conductive layer, an insulation layer, etc. The first reaction gas may include TEMAZ. Further, the first reaction gas may be introduced into the reaction chamber while maintaining the object with a first temperature. The first temperature may be in a range of about 240° C. to about 260° C.

A remaining first reaction gas may be removed from the reaction chamber using a first purge gas. For example, the first purge gas may include an argon gas, a helium gas, a xenon gas and/or a nitrogen gas. While removing the remaining first reaction gas from the object by a first purge step, the process temperature in the ALD process may be increased to a second temperature from the first temperature. The second temperature may be substantially higher than the first temperature. For example, the second temperature may be in a range of about 265° C. to about 285° C.

A second reaction gas may be introduced onto the absorption film while maintaining the reaction chamber with the second temperature. The second reaction gas may include an oxidizing agent. For example, the second reaction gas may include an oxygen gas, an ozone gas, a water vapor, etc. These may be used alone or in a mixture thereof. When the second reaction gas is reacted with the absorption film, a zirconium oxide layer may be provided on the object. When the second reaction gas includes the oxygen gas having relatively low oxidizing power, carbon and/or nitrogen may be partially oxidized to provide the zirconium oxide film somewhat including carbon and/or nitrogen.

A second purge step may be carried out to remove a remaining second reaction gas from the reaction chamber. The second purge step may be executed using a second purge gas including an inactive gas. For example, the second purge gas may include a nitrogen gas, an argon gas, a helium gas, a xenon gas, etc. These may be used alone or in a mixture thereof. While performing the second purge step, the object may be maintained with the second temperature. Alternatively, the process temperature may be reduced to the first temperature in the second purge step.

A third reaction gas may be introduced onto the zirconium oxide layer while treating the zirconium oxide layer with plasma, so that a zirconium oxynitride layer may be formed on the object. The third reaction gas and/or the plasma may include as a nitrifying agent such as nitrogen. For example, the third reaction gas and/or the plasma may include nitrogen monoxide (NO), nitrogen dioxide (NO₂), ammonia (NH₃), etc. These may be used alone or in a mixture thereof. In other words, the plasma may be generated from a nitrogen monoxide gas, a nitrogen dioxide gas and/or an ammonia gas. Because the step coverage of the zirconium oxynitride layer may mainly depend on the process temperature in the ALD process while providing the second reaction gas, the process temperature during providing the third reaction gas may be either the second temperature or the first temperature. That is, the process temperature during providing the third reaction gas may be substantially higher than or substantially similar to the first temperature.

A third purge step may be performed about the reaction chamber to remove a remaining third reaction gas or an unreacted third reaction gas. The remaining third gas may be purged using a third purge gas including an inactive gas. For example, the third purge gas may include an argon gas, a helium gas, a nitrogen gas, a xenon gas, etc. These may be used alone or in a mixture thereof.

When the above-described cycle of the ALD process is repeated, a zirconium oxynitride layer having a desired thickness may be formed on the object. For example, the zirconium oxynitride layer may have a thickness of about 10 Å to about 50 Å by repeating the cycle of the ALD process with about 20 times to about 50 times.

As described above, the zirconium oxynitride layer may ensure good step coverage and enhanced leakage current characteristics because the zirconium oxynitride layer may be obtained by varying the process temperature in the ALD process. Further, the zirconium oxynitride layer may have proper contents of ingredients such as nitrogen, carbon, zirconium, oxygen, etc. Carbon and/or nitrogen in the zirconium oxynitride layer may prevent the zirconium oxynitride layer from being crystallized.

When the zirconium oxide layer or the zirconium oxynitride layer is used as a gate insulation layer, a tunnel insulation layer or a dielectric layer in a semiconductor device such as a transistor, a semiconductor memory device or a capacitor, the semiconductor device may also have desired electrical characteristics. In example embodiments, the dielectric layer of the semiconductor device may have a multi layer structure that includes at least one zirconium oxide layer and at least one zirconium oxynitride layer.

In some example embodiments, other metal oxynitride layer may be formed on an object by an ALD process substantially similar to the above-described ALD process. For example, an aluminum oxynitride layer, a tantalum oxynitride layer or a titanium oxynitride layer having good step coverage and desired leakage current characteristics may be obtained by varying the process temperature in the ALD process. Further, a metal oxynitride layer, which includes at least one of the zirconium oxynitride layer, the aluminum oxynitride layer, the tantalum oxynitride layer and the titanium oxynitride layer, may be provided on an object through ALD processes substantially similar to the above-described ALD process.

### An Apparatus for Forming a Zirconium Oxide Layer and a Zirconium Oxynitride Layer

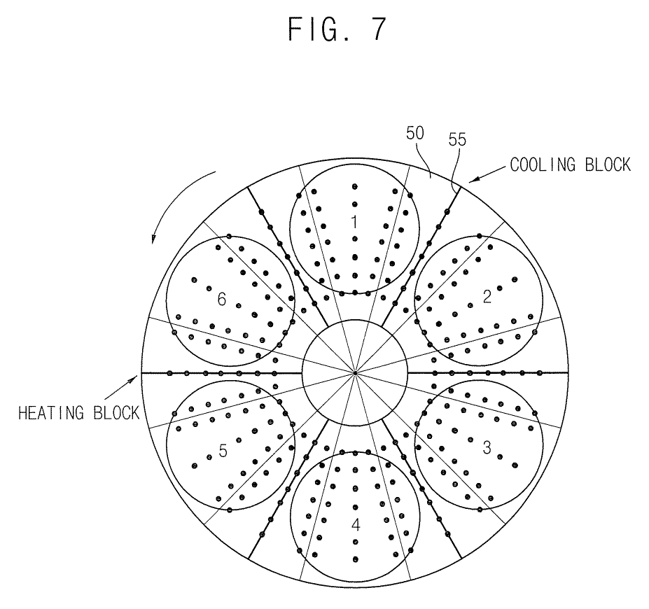

FIG. 7 is a plan view illustrating an apparatus for performing an ALD process in accordance with example embodiments.

Referring to FIG. 7, the apparatus includes a reaction chamber (not illustrated), a heating block, a cooling block and a substrate holder 50.

A plurality of substrates may be loaded on the substrate holder 50 disposed in the reaction chamber. The substrate holder 50 may be divided into a plurality of sections on which the substrates are positioned. That is, the apparatus may simultaneously process several substrates. The sections of the substrate holder 50 may be referred as reference numerals 1, 2, 3, 4, 5 and 6. However, the number of the sections of the substrate holder 50 may vary as occasion demands.

In example embodiments, the substrate holder 50 may include separation walls for separation the sections of the substrate holder 50. For example, the substrate holder 50 may have five separation walls when the substrate holder 50 is divided into sixe sections as illustrated in FIG. 7. However, the number of the separation walls may vary in accordance with the number of the sections in the substrate holder 50.

The heating block may include a heating member for heating the substrates to the desired process temperature in the ALD process. In example embodiments, the heating block may include an ultraviolet (UV) lamp, a halogen lamp, a heater, etc. These may be used alone or in a combination thereof. For example, the heating block may include a UV lamp and a halogen lamp, a halogen lamp and a heater, a UV lamp and a heater, etc. The heating block may heat the substrates to have a relatively high temperature (e.g., a temperature in a range of about 265° C. to 285° C.) within a desired short time.

The apparatus further includes a gas supply line 15 extending over the substrate holder 10, and a controller for controlling the process conditions in the ALD process. For example, the controller may adjust the type and the flow rate of reaction gases, the type and the flow rate of purging gases, a rotation speed of the substrate holder 10, the temperatures of the sections in the substrate holder 10, etc.

The gat supply line 15 provides the reaction gases and the purge gases onto the substrates loaded on the substrate holder 10. The gas supply line 15 may have a circular structure that extends over the substrate holder 10. Here, the gas supply line 15 may have a plurality of nozzles for providing the reaction gases and/or the purge gases onto the substrates placed in the sections of the substrate holder 10.

In some example embodiments, the sections of the substrate holder 10 may be separated by air curtains. Here, air for separating the sections of the substrate holder 10 may also be provided through the gas supply line 15.

When the sections of the substrate holder 10 are separated from one another, the substrates may be continuously processed. For example, a first reaction gas including TEMAZ may be provided onto the substrate positioned in the section 1 of the substrate holder 10 at a first temperature in a range of about 240° C. to about 260° C., and then an unreacted first reaction gas may be purged using an argon gas while transferring the substrate from the section 1 to the section 6. Thus, an absorption film may be formed on the substrate. A second reaction gas including an oxidizing agent may be provided onto the substrate while moving the substrate from the section 6 to the section 5. Here, the heating block may heat the substrate to have a second temperature substantially higher than the first temperature. The second temperature may be in a range of about 265° C. to about 285° C. The second reaction gas may be reacted with the absorption layer to form a zirconium oxide layer on the substrate while the substrate passes the section 4 and the section 3. In the section 2, an unreacted second reaction gas may be purged from the substrate, so that one cycle of the ALD process may be completed. While the substrate passes the cooling block, the temperature of the substrate may be reduced by a cooling gas including a helium gas. Namely, the cooling block may provide the substrate with the cooling gas to decrease the temperature of the substrate. The cooling gas may include an inactive gas having a temperature substantially similar to the first temperature.

In example embodiments, the substrate holder 10 having a plurality of substrates may rotate while forming zirconium oxide layers on the substrate, respectively. The substrates may be continuously processed by providing the reaction gases, the purge gases and the cooling gas while moving the substrate from the section 1 to the section 6. The rotation speed of the substrate holder 10 and the temperature of the substrates may be adjusted by the controller. Further, the flow rates of the reaction gases, the purging gases and the cooling gas may also be controlled by the controller.

In example embodiments, the substrates may be constantly heated or cooled by the heating block and the cooling block, and also the process conditions in the ALD process may be properly adjusted by the controller in accordance with the process temperatures of the substrates.

In some example embodiments, other metal oxide layers may be formed on the substrates using the apparatus for performing the ALD process. For example, aluminum oxide layers, tantalum oxide layers or titanium oxide layers having good step coverage and desired leakage current characteristics may be obtained using the apparatus for performing the ALD process. Further, a metal oxide layer, which includes at least one of the zirconium oxide layer, the aluminum oxide layer, the tantalum oxide layer and the titanium oxide layer, may be provided on the substrate using the above-described apparatus.

In the formations of a plurality of zirconium oxynitride layers on the substrates, a first reaction gas including TEMAZ may be provided onto the substrate positioned in the section 1 of the substrate holder 10 at a first temperature, and then an unreacted first reaction gas may be purged using an argon gas while transferring the substrate from the section 1 to the section 6. Thus, an absorption layer may be formed on the substrate. A second reaction gas including an oxidizing agent may be provided onto the substrate while moving the substrate from the section 6 to the section 5. Here, the heating block may heat the substrate to have a second temperature substantially higher than the first temperature. Hence, a zirconium oxide layer is formed on the substrate while positioning the substrate in the section 5. A third reaction gas including nitrogen may be provided onto the zirconium oxide layer while the substrate passes the section 4. An unreacted third reaction gas may be purged while moving the substrate from the section 4 to the section 3. In the section 3, the zirconium oxide layer may be nitrified to form the zirconium oxynitride layer on the substrate. Remaining by-products and reaction gases may be purged from the substrate in the section 2, such that one cycle of the ALD process may be completed. While the substrate passes the cooling block, the temperature of the substrate may be reduced by a cooling gas.

In some example embodiments, other metal oxynitride layers may be formed on the substrates using the apparatus for performing the ALD process. For example, aluminum oxynitride layers, tantalum oxynitride layers or titanium oxynitride layers having good step coverage and desired leakage current characteristics may be obtained using the apparatus for performing the ALD process. Further, a metal oxynitride layer, which includes at least one of the zirconium oxynitride layer, the aluminum oxynitride layer, the tantalum oxynitride layer and the titanium oxynitride layer, may be provided on the substrate using the above-described apparatus.

According to example embodiments, the apparatus for performing the ALD process includes the substrate holder and the heating block, a plurality of zirconium compound layers may be simultaneously provided on a plurality of substrates. Thus, the yield of manufacturing semiconductor devices may be considerably improved.

### Method of Manufacturing Semiconductor Devices

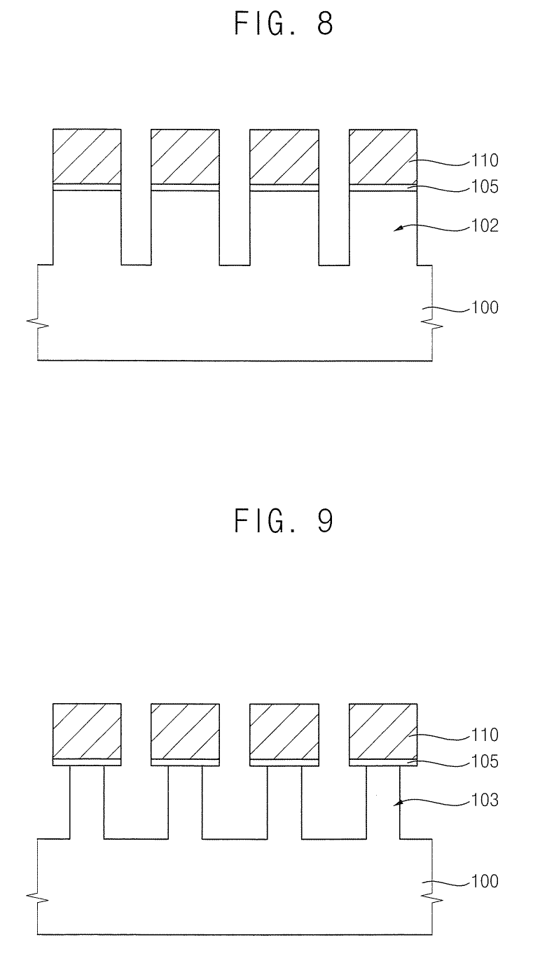

FIGS. 8 to 23 are cross sectional views illustrating a method of manufacturing a semiconductor device in accordance with example embodiments.

Referring to FIG. 8, a pad oxide layer (not illustrated) is formed on a substrate 100. For example, the substrate 100 may include a semiconductor substrate such as a silicon substrate, a germanium substrate, a silicon-germanium substrate, etc. Alternatively, the substrate 100 may include an SOI substrate or a GOI substrate. The pad oxide layer may be formed by a chemical vapor deposition (CVD) process or a thermal oxidation process. The pad oxide layer may include silicon oxide when the substrate 100 includes silicon. The pad oxide layer may have a thickness of about 50 Å to about 150 Å.

A mask layer (not illustrated) is formed on the pad oxide layer. The mask layer may be formed using material having an etching selectivity relative to the pad oxide layer and the substrate 100. For example, the mask layer may include nitride such as silicon nitride and/or oxynitride like silicon oxynitride. The mask layer may be formed on the pad oxide layer by a CVD process, a plasma enhanced chemical vapor deposition (PECVD) process, a low pressure chemical vapor deposition (LPCVD) process, etc.

The mask layer and the pad oxide layer are etched to form a first mask 110 and a pad oxide layer pattern 105 on the substrate 100. The first mask 110 may have a thickness substantially larger than that of the pad oxide layer pattern 105.

The substrate 100 is partially etched using the first mask 110 and the pad oxide layer pattern 105 as etching masks, so that a plurality of preliminary pillar structures 102 is formed on the substrate 100. Each of the preliminary pillar structures 102 may have a height in a range of about 800 Å to about 1,500 Å. The preliminary pillar structures 102 may have cylindrical column shapes or polygonal column shapes, respectively.

Referring to FIG. 9, the preliminary pillar structures 102 are partially etched to form pillar structures 103 on the substrate 100. The pillar structures 103 may be obtained by an anisotropic etching process. For example, the pillar structures 103 may be formed by a wet etching process or a chemical dry etching process. In example embodiments, lateral portion of the preliminary pillar structures 102 may be partially removed to provide the pillar structures 103 having widths substantially smaller than those of the preliminary pillar structures 103. Thus, each of the pillar structures 103 may have a width substantially smaller to that of the first mask 110. For example, each of the pillar structures 103 may have a width of about 200 Å to about 300 Å. Each of the pillar structures 103 may also have a cylindrical column shape or a polygonal column shape.

Referring to FIG. 10, a gate insulation layer 115 is formed on the substrate 100 and sidewalls of the pillar structures 103. The gate insulation layer 115 may be uniformly formed on the substrate 100 to enclose the pillar structures 103. The gate insulation layer 115 may be formed using oxide or metal compound by a CVD process, an ALD process, a sputtering process, a pulsed laser deposition (PLD) process, an evaporation process, etc. For example, the gate insulation layer 115 may include silicon oxide, hafinium oxide (HfOx), aluminum oxide (AlOx), titanium oxide (TiOx), zirconium oxide (ZrOx), zirconium oxynitride (ZrOxNy), tantalum oxide (TaOx), titanium oxynitride (TiOxNy), aluminum oxynitride (AlOxNy), tantalum oxynitide (TaOxNy), etc. Alternatively, the gate insulation layer 115 may have a multi layer structure that includes a first oxide film, a nitride film and a second oxide film.

In example embodiments, the gate insulation layer 115 may include a metal oxide film and/or a metal oxynitride film obtained by an ALD process substantially the same as or substantially similar to the above-described ALD process. For example, the gate insulation layer 115 may include a zirconium oxide film and/or a zirconium oxynitride film.

A gate electrode layer 120 is formed on the gate insulation layer 115 and the first mask 110. The gate electrode layer 120 may have a sufficient thickness that fully fills up a gap between adjacent pillar structures 103. The gate electrode layer 120 may be formed using polysilicon, metal and/or metal compound. For example, the gate electrode layer 120 may include polysilicon doped with impurities, tungsten (W), aluminum (Al), titanium (Ti), tantalum (Ta), tungsten nitride (WNx), titanium nitride (TiNx), aluminum nitride (AlNx), tantalum nitride (TaNx), tungsten silicide (WSix), titanium silicide (TiSix), cobalt silicide (CoSix), nickel silicide (NiSix), etc. These may be used alone or in a mixture thereof. Further, the gate electrode layer 120 may be formed by a CVD process, an ALD process, a PECVD process, a sputtering process, a PLD process, an evaporation process, etc.

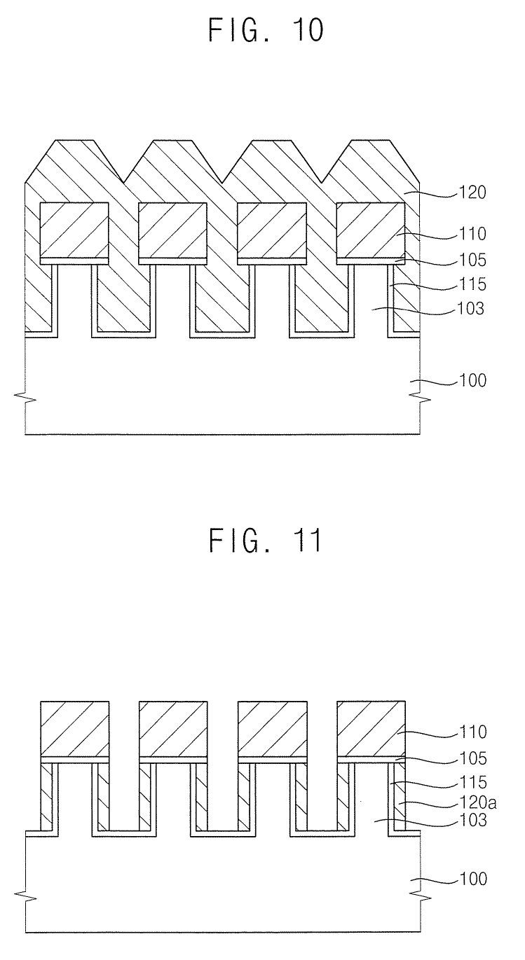

Referring to FIG. 11, the gate electrode layer 120 is etched to form a gate electrode 120a on the gate insulation layer 115 positioned on the sidewall of the pillar structures 103. Here, the first mask 110 and the pad oxide layer pattern 105 may serve as etching masks for forming the gate electrode 120a. The gate electrode 120a may enclose the sidewall of the pillar structures 103 by interposing the gate insulation layer 115.

In example embodiments, the total width of the gate electrode 120a, the gate insulation layer 115 and the pillar structures 103 may be substantially the same as or substantially similar to that of the first mask 110.

Referring to FIG. 12, first impurity regions 125 are formed at portions of the substrate 100 between adjacent pillar structures 103. The first impurity regions 125 may be formed by doping impurities into the portions of the substrate 100 as indicated using arrows. The first impurity regions 125 may serve as source/drain regions. The first impurity regions 125 may extend beneath the gate electrode 120a and the gate insulation layer 115.

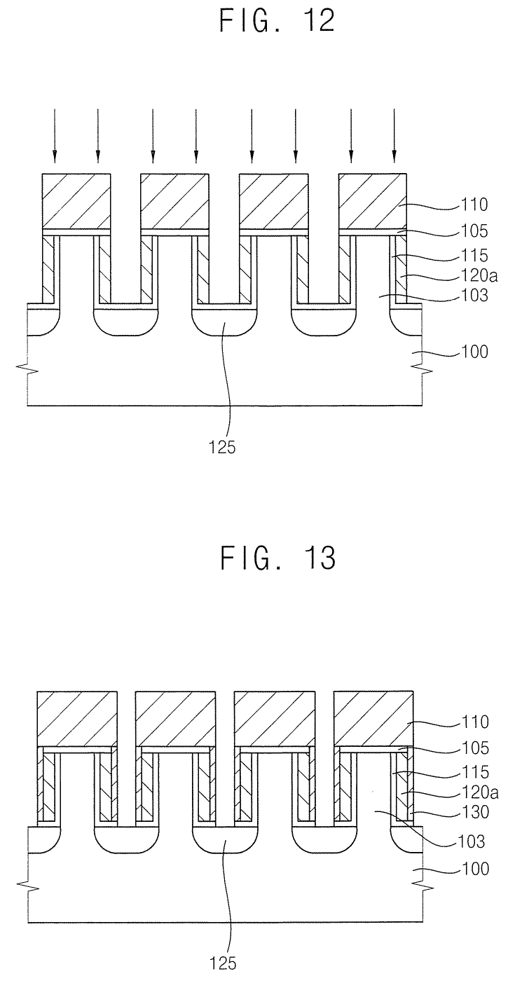

Referring to FIG. 13, an insulation layer (not illustrated) is formed on the first impurity regions 125, the gate electrode 120a and the first mask 110. The insulation layer may be formed using nitride such as silicon nitride by a CVD process, a PECVD process, an LPCVD process, etc. The insulation layer may have a thickness of about 200 Å to about 400 Å.

The insulation layer is etched to form a second mask 130 on sidewalls of the gate electrode 120a and the pad oxide layer pattern 105. The second mask 130 may be obtained by anisotropic etching process. The second mask 130 may expose an end portion of the gate insulation layer 115.

Referring to FIG. 14, the first impurity region 125 is partially etched using the second mask 130 as an etching mask. That is, a portion of the first impurity region 125 between adjacent gate electrodes 120a is partially etched to provide a groove or a recess 135 on the first impurity region 125. Hence, a central portion of the first impurity region 125 may be substantially lower than a peripheral portion of the first impurity region 125. The central portion of the first impurity region 125 is exposed through the recess 135 whereas the peripheral portion of the first impurity region 125 is positioned beneath the gate electrode 120a.

A protection layer 140 is formed on a sidewall of the recess 135. The protection layer 140 may be formed a thermal oxidation process or a CVD process. In example embodiments, the protection layer 140 may include a material substantially the same or substantially similar to that of the gate insulation layer 115. For example, the protection layer 140 may include silicon oxide or metal compound.

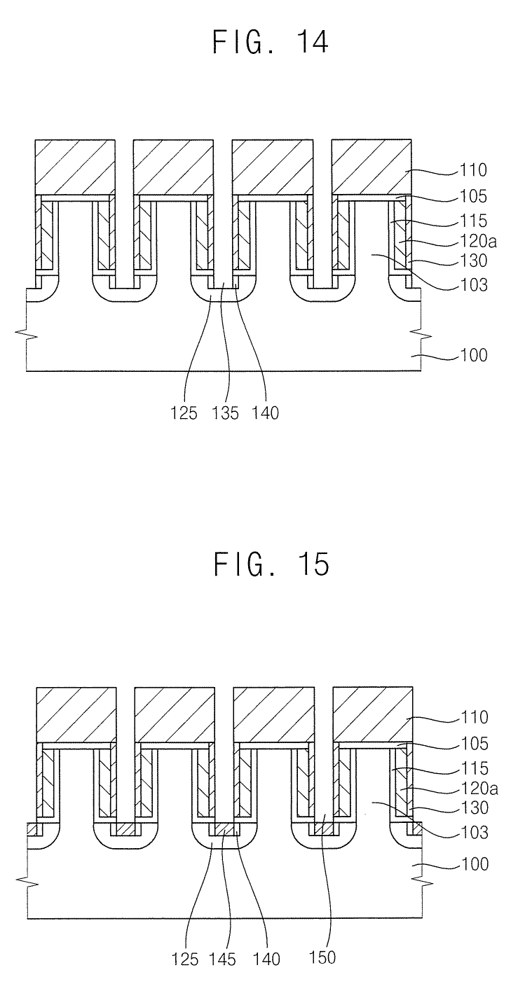

Referring to FIG. 15, a bit line 145 is formed on the first impurity region 125 to fill up the recess 135. Here, the protection layer 140 may electrically insulate the gate electrode 120a from the bit line 145. The bit line 145 may be formed using polysilicon, metal and/or metal compound. For example, the bit line 145 may include polysilicon doped with impurities, titanium, aluminum, nickel, tantalum, tungsten, titanium nitride, tungsten nitride, aluminum nitride, titanium silicide, nickel silicide, cobalt silicide, etc. These may be used alone or in a mixture thereof.

In example embodiments, the bit line 145 may have a thickness of about 100 Å to about 300 Å. The bit line 145 may be formed by a CVD process, an ALD process, a PECVD process, a sputtering process, a PLD process, an evaporation process, etc. Since the protection layer 140 is provided on the sidewall of the recess 135, the bit line 145 may be effectively insulated from the gate electrode 120a.

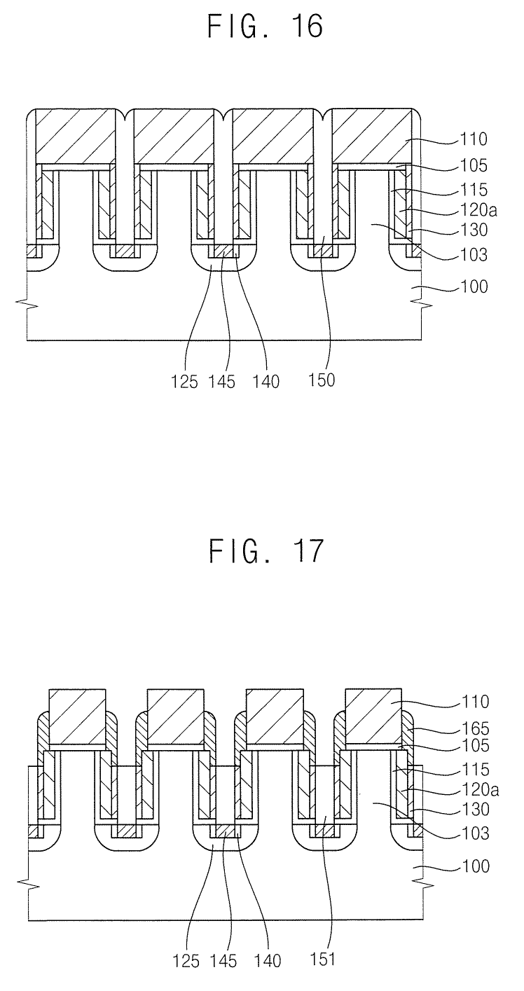

Referring to FIG. 16, a first insulation layer 150 is formed on the bit line 145 to fully fill up a gap between adjacent gate electrodes 120a or adjacent pillar structures 103. The first insulation layer 150 may be formed using oxide by a CVD process, a PECVD process, a spin coating process, an LPCVD process, an HDP-CVD process, etc. For example, the first insulation layer 150 may include undoped silicate glass (USG), spin on glass (SOG), flowable oxide (FOX), boro-phosphor silicate glass (BPSG), phosphor silicate glass (PSG), tetra ethyl ortho silicate (TEOS), plasma enhanced-TOES (PE-TEOS), tonen silazene (TOSZ), HDP-CVD oxide, etc.

In example embodiments, the first insulation layer 150 may be planarized by a chemical mechanical polishing (CMP) process and/or an etch-back process to ensure a level upper face of the first insulation layer 150.

Referring to FIG. 17, the first insulation layer 150 is partially etched to form an insulation layer pattern 151 between adjacent gate electrodes 120a. The first insulation layer pattern 151 may have a height substantially smaller than that of the gate electrode 120a.

The first mask 110, the pad oxide layer pattern 105 and the second mask 130 are partially etched to expose a portion of the gate electrode 120a. For example, an upper side portion of the gate electrode 120a may be exposed after partially removing the first mask 110, the pad oxide layer pattern 105 and the second mask 130.

A conductive member 165 is formed on the sidewalls of the first mask 110 and the pad oxide layer pattern 105 to cover the exposed portion of the gate electrode 120a. Thus, the conductive member 165 may be electrically connected to the gate electrode 120a. The conductive member 165 may have a spacer structure positioned from the second mask 130 to the first mask 110. The conductive member 165 may be supported by the second mask 130.

In example embodiments, the conductive member 165 may be formed using metal and/or metal compound by a sputtering process, a CVD process, an ALD process, a PLD process, an evaporation process, etc. For example, the conductive member 165 may include titanium, titanium nitride, titanium silicide, cobalt silicide, nickel, nickel silicide, tungsten, tungsten nitride, aluminum nitride, etc. These may be used alone or in a mixture thereof. The conductive member 165 may have a thickness of about 100 Å to about 300.

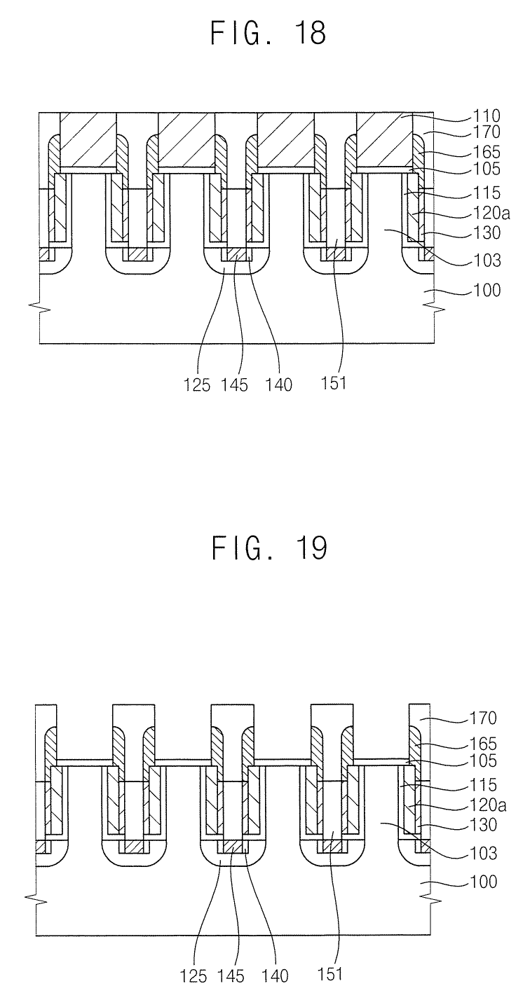

Referring to FIG. 18, a second insulation layer 170 is formed on the first insulation layer pattern 151 and the conductive member 165. The second insulation layer 170 may fully fill up a gap between adjacent conductive members 165. The second insulation layer 170 may be formed using oxide by a CVD process, a PECVD process, a spin coating process, an LPCVD process, an HDP-CVD process, etc. For example, the second insulation layer 170 may include USG, SOG, FOX, BPSG, PSG, TEOS, PE-TEOS, TOSZ, HDP-CVD oxide, etc.

In example embodiments, the second insulation layer 170 may include oxide substantially the same as or substantially similar to that of the first insulation layer pattern 151. Alternatively, the second insulation layer 170 may include oxide different from that of the first insulation layer pattern 151. The second insulation layer 170 may be planarized to have a flat upper face. Here, the flat upper face of the second insulation layer 170 may be obtained by the CMP process and/or an etch-back process.

Referring to FIG. 19, the first mask 110 is removed from the pad oxide layer pattern 105, and thus the pad oxide layer pattern 105 is exposed. When the first mask 110 includes nitride, the first hard mask 110 may be etched using an etching solution including phosphoric acid. After removing the first hard mask 110, the second insulation layer 170 and the conductive member 165 are protruded over the pad oxide layer pattern 105.

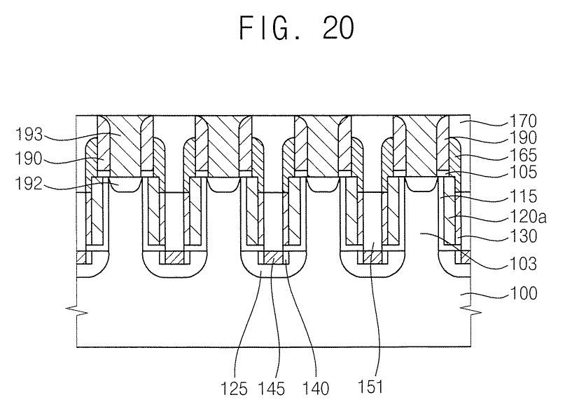

Referring to FIG. 20, a spacer 190 is formed on sidewalls of the conductive member 165 and the second insulation layer 170. The spacer 190 may be formed using nitride by a CVD process, a PECVD process, an LPCVD process, etc. In example embodiments, the spacer 190 may be formed by etching a spacer formation layer after conformally forming the spacer formation layer on the pad oxide layer pattern 105, the second insulation layer 170 and the conductive member 165.

A second impurity region 192 is formed at an upper portion of the pillar structure 103 after partially removing the pad oxide layer pattern 105 using the spacer 190 as an etching mask. When the pad oxide layer pattern 105 is partially removed, the upper portion of the pillar structure 103 is exposed, and the second impurity region 192 is formed at the exposed portion of the pillar 103. The second impurity region 192 may be formed by an ion implantation process using the spacer 190 as an implantation mask.

In example embodiments, the second impurity region 192 may be disposed between adjacent first impurity regions 125. That is, the first impurity region 125 and the second impurity region 192 may be alternately arranged. A channel region may be formed at a portion of the pillar structure 103 between the first impurity region 125 and the second impurity region 192.

A contact or a pad 193 is formed on the second impurity region 192 to fill up a gap between adjacent spacers 190. Here, the spacer 190 may electrically insulate the conductive member 165 from the pad 193. The pad 193 may be formed using polysilicon, metal and/or metal compound by a sputtering process, a CVD process, an ALD process, a PECVD process, a PLD process, an evaporation process, etc. For example, the pad 193 may be formed using polysilicon doped with impurities, titanium, tungsten, aluminum, nickel, tantalum, copper, titanium nitride, tungsten nitride, aluminum nitride, nickel silicide, cobalt silicide, titanium silicide, etc. These may be used alone or in a mixture thereof.

In example embodiments, the pad 193 may be formed by partially removing a conductive layer after forming the conductive layer on the second insulation layer 170 to fill up the gap between adjacent spacers 190. Here, the conductive layer may be planarized by a CMP process and/or an etch-back process.

Referring to FIG. 21, an etch stop layer 194 is formed on the second insulation layer 170 and the pad 193. The etch stop layer 194 may be formed using a material that has an etching selectivity relative to oxide, metal and metal compound. For example, the etch stop layer 194 may be formed using nitride such as silicon nitride. Further, the etch stop layer 194 may be formed by a CVD process, a PECVD process, an LPCVD, etc.

A lower electrode 195 is formed on the pad 193 through the etch stop layer 194. The lower electrode 195 may have a cylindrical structure. The lower electrode 195 may be formed using polysilicon, metal and/or metal compound by a sputtering process, a CVD process, an ALD process, a PECVD process, a PLD process, an evaporation process, etc. For example, the lower electrode 195 may include polysilicon doped with impurities, titanium, tungsten, aluminum, platinum, nickel, tantalum, copper, titanium nitride, tungsten nitride, aluminum nitride, etc. These may be used alone or in a mixture thereof.

In example embodiments, the lower electrode 195 may be provided on the pad 193 using a mold layer. The mold layer may be formed using oxide by a CVD process, a PECVD process, an LPCVD process, an HDP-CVD process, etc. For example, the mold layer may include USG, FOX, TOSZ, TEOS, PE-TEOS, HDP-CVD oxide, etc. After the mold layer may be formed on the etch stop layer 194, the mold layer and the etch stop layer 194 may be partially etched to form an opening that exposes the pad 193.

In some example embodiments, a lower electrode layer may be formed on the pad 193, a sidewall of the opening and the mold layer, and then a sacrificial layer may be formed on the lower electrode layer to fill up the opening. The lower electrode layer may be formed using polysilicon, metal and/or metal compound by a sputtering process, a CVD process, a PECVD process, an ALD process, a PLD process, an evaporation process, etc. The sacrificial layer may be formed using an organic material such as photoresist. Alternatively, the sacrificial layer may include oxide such as silicon oxide. The lower electrode layer may be partially removed until the mold layer may be exposed. When the mold layer and the sacrificial layer may be removed, the lower electrode 195 may be formed on the pad 193. The mold layer and the sacrificial layer may be removed by a lift off process using an LAL solution when the mold and the sacrificial layers include oxides. Alternatively, the sacrificial layer may be removed from the lower electrode 195 after removing the mold layer in case that the mold layer and the sacrificial layer include different materials, respectively.

In example embodiments, the lower electrode 195 may have a rounded upper portion by a wet etching process. For example, an upper edge portion of the lower electrode 195 may be rounded. When the lower electrode 195 has the rounded upper portion, the dielectric layer may be uniformly and conformally formed on the entire portion of the lower electrode 195.

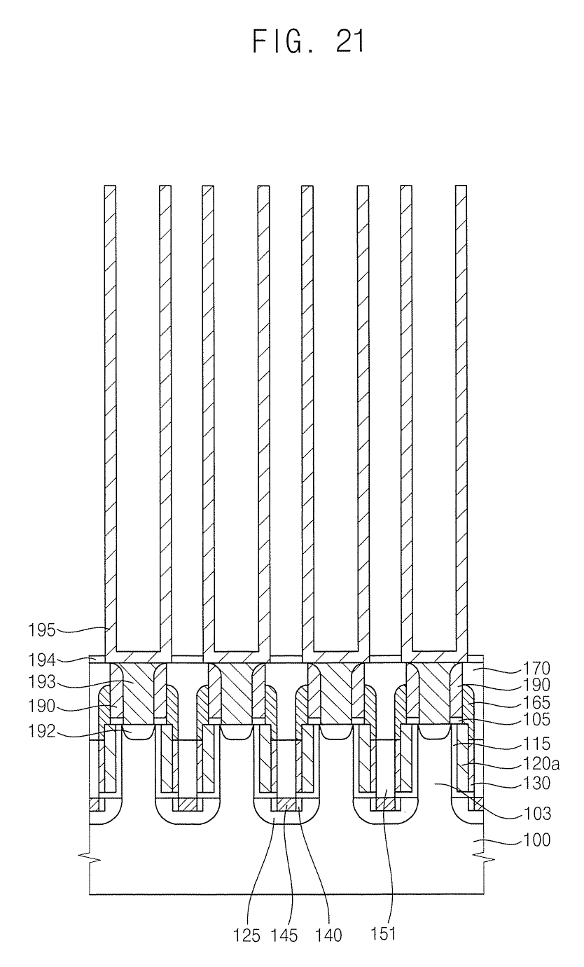

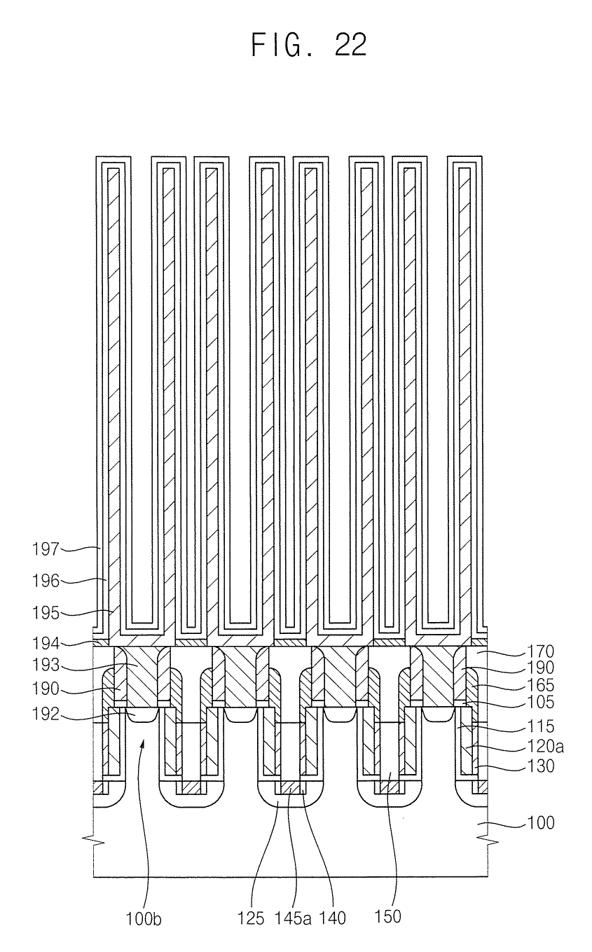

Referring to FIG. 22, a dielectric layer is formed the lower electrode 195. The dielectric layer may be obtained by an ALD process substantially the same as or substantially similar to the above-described ALD process. For example, the dielectric layer may include zirconium oxide and/or zirconium oxynitride while changing the process temperature in the ALD process. Alternatively, the dielectric layer may have a multi layer structure that includes at least one oxide film, at least one metal oxide film and/or at least one oxynitride film. For example, the dielectric layer includes a metal oxide film 196 and a metal oxynitride film 197. Here, the metal oxide film 196 may include zirconium oxide, hafnium oxide, titanium oxide, tantalum oxide, aluminum oxide, etc. Further, the metal oxynitride film 197 may include zirconium oxynitride, hafnium oxynitride, titanium oxynitride, tantalum oxynitride, aluminum oxynitride, etc.

When the dielectric layer has the metal oxide and the metal oxynitride films 196 and 197 obtained through the above-described ALD processes, the dielectric layer may be uniformly formed on the entire portion of the lower electrode 195. Further, the dielectric layer including the metal oxide and the metal oxynitride films 196 and 197 may ensure enhanced electrical characteristics such as improved leakage current characteristics.

In example embodiments, the metal oxide film 196 may include zirconium oxide formed through an ALD process substantially the same as or substantially similar to the above-described ALD process. Here, the metal oxide film 196 may have a thickness of about 100 Å to about 200 Å. The metal oxynitride film 197 is positioned on the metal oxide film 196. The metal oxynitride film 197 may include zirconium oxynitride obtained through an ALD process substantially the same as or substantially similar to the above-described ALD process. The metal oxynitride film 197 may have a thickness of about 50 Å to about 150 Å, so that a thickness ratio between the metal oxide film 196 and the metal oxynitride film 197 may be in a range of about 1.0:0.5 to about 1.0:1.5.

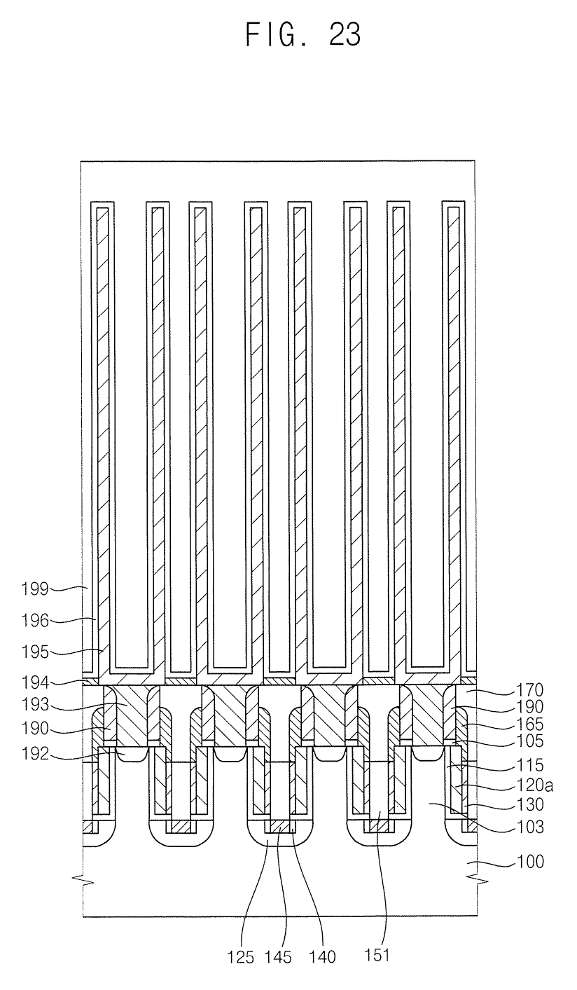

Referring to FIG. 23, an upper electrode 199 is formed on the dielectric layer. The upper electrode 199 may be formed using polysilicon, metal and/or metal compound. For example, the upper electrode 199 may include polysilicon doped with impurities, platinum, tungsten, titanium, tantalum, aluminum, nickel, titanium nitride, aluminum nitride, tungsten nitride, tantalum nitride, etc. These may be used alone or in a mixture thereof. Further, the upper electrode 199 may be formed by a sputtering process, a CVD process, an ALD process, a PECVD process, a PLD process, an evaporation process, etc. When the upper electrode 199 is formed, a capacitor having the lower electrode 195, the dielectric layer and the upper electrode 199 is provided on the pad 193.

In some example embodiments, an additional insulation layer and a wiring may be formed on the upper electrode 199 to provide a semiconductor device on the substrate 100. The additional insulation layer may be formed using oxide such as silicon oxide, and the wiring may be formed using metal and/or metal compound.

According to example embodiments, the dielectric layer may have desired step coverage and leakage current characteristics so that the semiconductor device including the dielectric layer may ensure good electrical characteristics such as improved reliability, constant threshold voltage, reduced leakage current, etc.

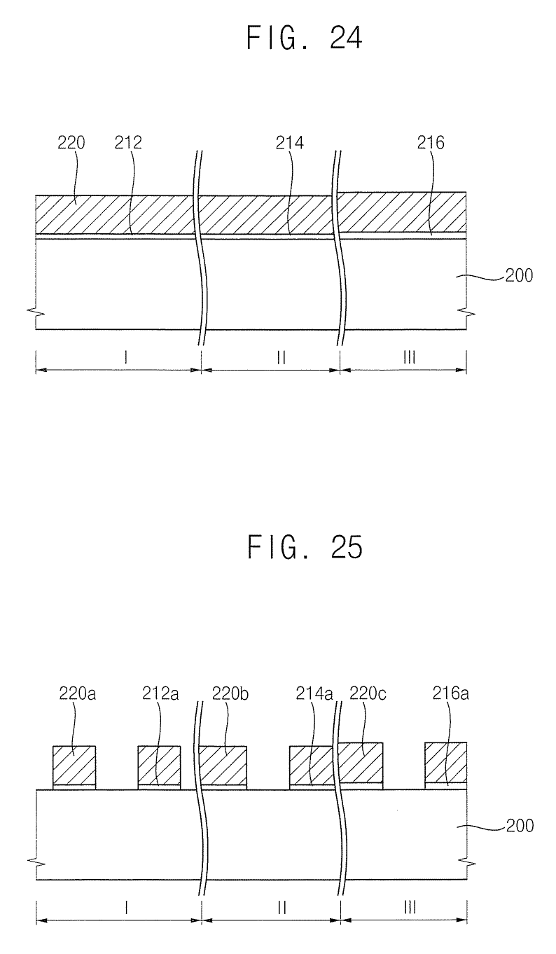

FIGS. 24 to 34 are cross sectional views illustrating a method of manufacturing a semiconductor device in accordance with example embodiments. Although FIGS. 24 to 34 illustrate a method of manufacturing a flash memory device, the features of the invention may be employed in other non-volatile semiconductor devices.

Referring to FIG. 24, a substrate 200 having a cell area I and a core/peripheral area is provided. The core/peripheral area is divided into a low voltage transistor area II and a high voltage transistor area III. In example embodiments, cell transistors may be formed in the cell area I and low voltage transistors may be provided in the low voltage transistor area II. Further, high voltage transistors may be positioned in the high voltage transistor area III.

The substrate 200 may include a semiconductor substrate. For example, the substrate 200 may include a silicon substrate, a germanium substrate, a silicon-germanium substrate, etc. Alternatively, the substrate 200 may include an SOI substrate, a GOI substrate, etc.

An insulation structure is formed on the substrate 200 having the cell area I, the low voltage transistor area II and the high voltage transistor area III. The insulation structure includes a first insulation layer 212, a second insulation layer 214 and a third insulation layer 216. The first insulation layer 212 is positioned in the cell area I. The second and the third insulation layers 214 and 216 are formed in the low and the high voltage transistor areas II and III. The first to the third insulation layers 212, 214 and 216 may be formed by a CVD process or a thermal oxidation process.

In example embodiments, the third insulation layer 216 may have a thickness substantially larger than those of the first and the second insulation layers 212 and 214. Here, the first insulation layer 212 may have a thickness substantially the same as or substantially similar to that of the second insulation layer 214. Each of the first to the third insulation layers 212, 214 and 216 may include oxide such as silicon oxide. For example, each of the first to the third insulation layers 212, 214 and 216 may include SOG, USG, FOX, TOSZ, TEOS, PE-TEOS, HDP-CVD oxide, etc.

A first conductive layer 220 is formed on the insulation structure. That is, the first conductive layer 220 is positioned on the first to the third insulation layers 212, 214 and 216. The first conductive layer 220 may be formed using polysilicon, metal and/or metal compound. For example, the first conductive layer 220 may include polysilicon doped with impurities, titanium, platinum, nickel, tungsten, aluminum, tantalum, titanium nitride, aluminum nitride, tungsten nitride, tantalum nitride, cobalt silicide, titanium silicide, tungsten silicide, zirconium silicide, etc. These may be used alone or in a mixture thereof. Additionally, the first conductive layer 220 may be formed by a sputtering process, a CVD process, a PECVD process, an ALD process, a PLD process, an evaporation process, etc.

In example embodiments, the first conductive layer 220 may have a thickness of about 500 Å to about 2,000 Å. The first conductive layer 220 may have a multi layer structure that includes at least one polysilicon film, a metal film and/or a metal compound film. For example, the first conductive layer 220 may include a first polysilicon film and a second polysilicon film. Here, the first polysilicon film may have a thickness of about 200 Å to about 500 Å, and the second polysilicon film may have a thickness in a range of about 300 Å to about 1,500 Å.

Referring to FIG. 25, after a mask (not illustrated) is provided on the first conductive layer 220, the first conductive layer 220 is etched to form a first electrode 220a, a second electrode 220b, and a third electrode 220c. Here, the insulation structure is also etched to form a first insulation layer pattern 212a, a second insulation layer pattern 214a, and a third insulation layer pattern 216a. The first insulation layer pattern 212a and the first electrode 220a are formed in the cell area I. The second insulation layer pattern 214a and the second electrode 220b are positioned in the low voltage transistor area II. The third insulation layer pattern 216a and the third electrode 220c are located in the high voltage transistor area III.

In example embodiments, a first interval between adjacent first electrodes may be substantially smaller than a third interval between adjacent third electrodes 216a. Further, a second interval between adjacent second electrodes 214a may be substantially similar to or substantially larger than the first interval between adjacent first electrodes 220a.

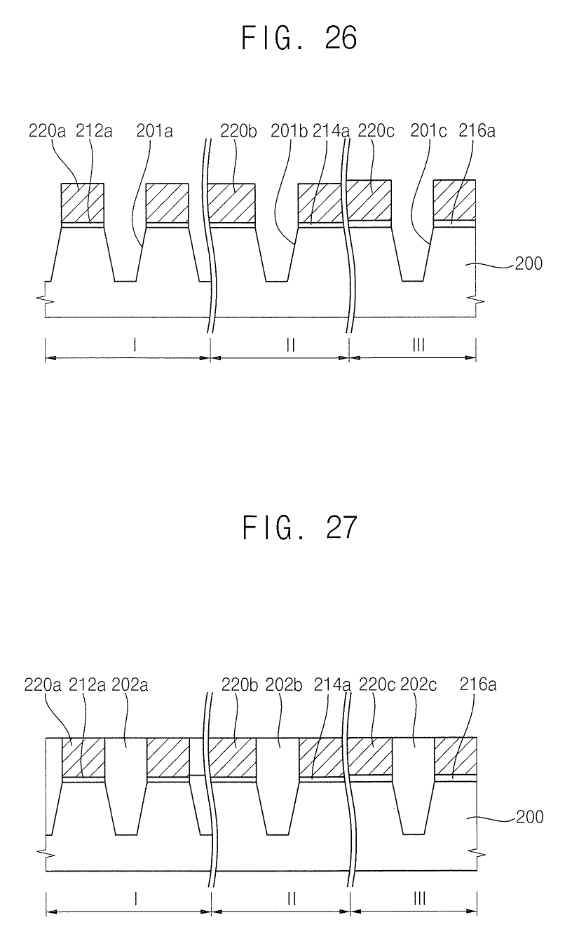

Referring to FIG. 26, the substrate 200 is partially etched using the first to the third electrodes 220a, 220b and 220c as etching masks to form a first trench 201a, a second trench 201b and a third trench 201c. The first trench 201a is positioned at a first portion of the substrate 200 between adjacent first electrodes 220a, and the second trench 201b is located at a second portion of the substrate 200 between adjacent second electrodes 214a. Additionally, the third trench 201c is formed at a third portion of the substrate 200 between adjacent third electrodes 216a.

In example embodiments, each of the first to the third trench 201a, 201b and 201c may have a sidewall inclined with respect to the substrate 200. Thus, the stress generated in the formation of the first to the third trenches 201a, 201b and 201c may be reduced. Further, the first to the third trenches 201a, 201b and 201c may be easily filled with isolation layers in a successive process. When the third interval between adjacent third electrodes 216a is larger than the first interval between adjacent first electrodes 212a or the second interval between adjacent second electrodes 214a, the third trench 201c may have a width substantially larger than that of the first trench 201a or the second trench 201b.

Referring to FIG. 27, a first preliminary isolation layer 202a, a second preliminary isolation layer 202b and a third preliminary isolation layer 202c are formed in the first trench 201a, the second trench 201b and the third trench 201c, respectively. The first to the third preliminary isolation layers 202a, 202b and 202c may be formed using oxide such as silicon oxide. For example, each of the first to the third preliminary isolation layers 202a, 202b and 202c may be formed using SOG USG, FOX, TOSZ, TEOS, PE-TEOS, HDP-CVD oxide, etc. Further, the first to the third preliminary isolation layers 202a, 202b and 202c may be formed by a CVD process, a PECVD process, a spin coating process, an HDP-CVD process, etc.

In example embodiments, each of the first to the third preliminary isolation layers 202a, 202b and 202c may have a multi layer structure including at least one oxide film. Further, each of the first to the third preliminary isolation layers 202a, 202b and 202c may have a level upper face through a planarization process such as a CMP process, an etch-back process, etc.

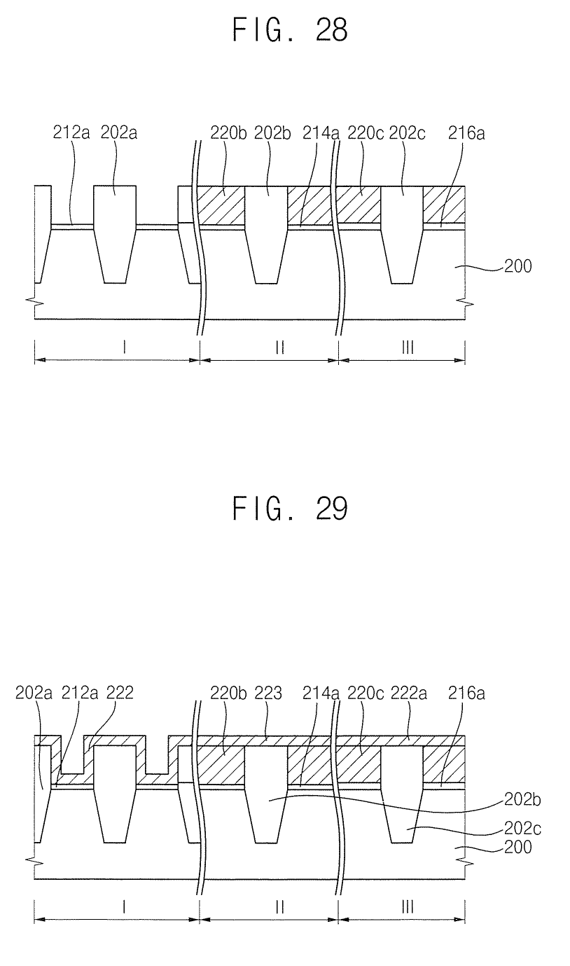

Referring to FIG. 28, the first electrode 212a is removed from the first insulation layer pattern 212a in the cell area I. Here, the low voltage and the high voltage transistor areas II and III may be covered with a protection mask containing photoresist. Namely, the second and the third electrodes 214a and 216a may be covered with the protection mask while etching the first electrode 220a. When the first electrode 220a is removed, the first preliminary isolation layer 202a is protruded over the first insulation layer pattern 212a. Hence, a U shape structure in the cell area I may be provided by a sidewall of the first preliminary isolation layer 202a and the first insulation layer pattern 212a.

Referring to FIG. 29, a conductive structure is formed on the substrate 200. The conductive structure includes a second conductive layer 222 and a third conductive layer 223. The second conductive layer 222 is conformally formed on the first insulation layer pattern 212a and the first preliminary isolation layer 202a along the profiles of the first insulation layer pattern 212a and the first preliminary isolation layer 202a. The third conductive layer 223 is positioned on the second electrode 220b, the second preliminary isolation layer 202b, the third electrode 220c and the third preliminary isolation layer 202c.

Each of the second and the third conductive layers 222 and 223 may be formed using polysilicon, metal and/or metal compound by a CVD process, a PECVD process, an ALD process, a sputtering process, a PLD process, an evaporation process, etc. For example, the second and the third conductive layers 222 and 223 may include polysilicon doped with impurities, titanium, platinum, nickel, tungsten, aluminum, tantalum, titanium nitride, aluminum nitride, tungsten nitride, tantalum nitride, cobalt silicide, titanium silicide, tungsten silicide, zirconium silicide, etc. These may be used alone or in a mixture thereof. Further, each of the second and the third conductive layers 222 and 223 may have a thickness of about 200 Å to about 500 Å.

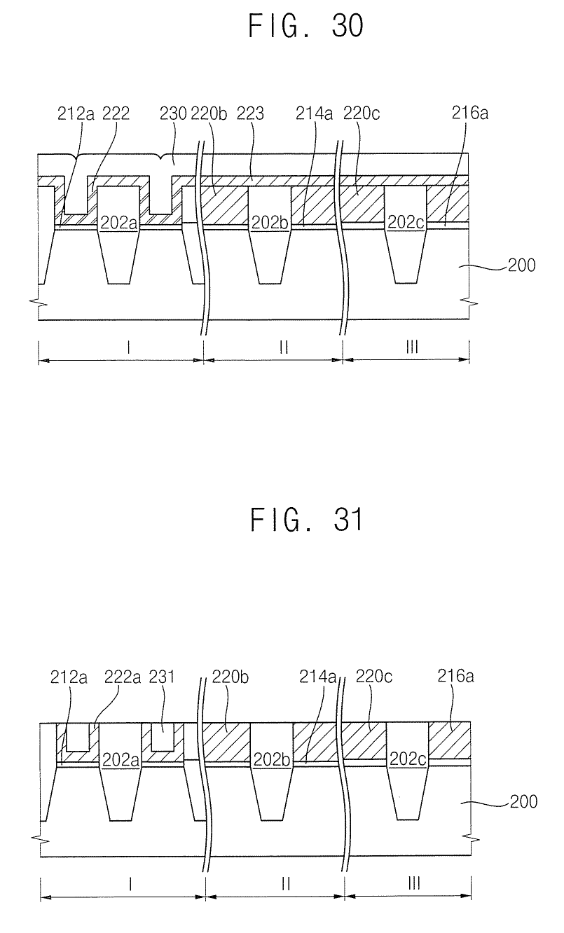

Referring to FIG. 30, a sacrificial layer 230 is formed on the second and the third conductive layers 222 and 223. The sacrificial layer 230 may be formed using oxide such as silicon oxide. For example, the sacrificial layer 230 may include USG, SOG, FOX, TOSZ, PSG, BPSG, TEOS, PE-TEOS, HDP-CVD oxide, etc. Further, the sacrificial layer 230 may be formed by a spin coating process, a CVD process, a PECVD process, an HDP-CVD process, etc.

In example embodiments, the sacrificial layer 230 may have a thickness sufficiently filling a gap between adjacent first preliminary isolation layers in the cell area I. Here, a dent or a recess may be generated at a portion of the sacrificial layer 230 positioned in the cell area I.

Referring to FIG. 31, the sacrificial layer 230 is partially removed until the second and the third electrodes 220b and 220c are exposed, so that a sacrificial layer pattern 231 and a floating gate 222a are formed on the first insulation layer pattern 214a in the cell area I of the substrate 200. The sacrificial layer pattern 231 and the floating gate 222a may be formed by a CMP process and/or an etch-back process.

In example embodiments, the floating gate 222a may have a U shape in accordance with the profiles of the first preliminary isolation layer 202a and the first insulation layer pattern 212a. That is, the floating gate 222a may have the U shape when the first preliminary isolation layer 202a and the first insulation layer pattern 212a provide the U shape structure in the cell area I. For example, the floating gate 202a may be located on the first insulation layer pattern 212a and the sidewall of the first preliminary isolation layer 202a.

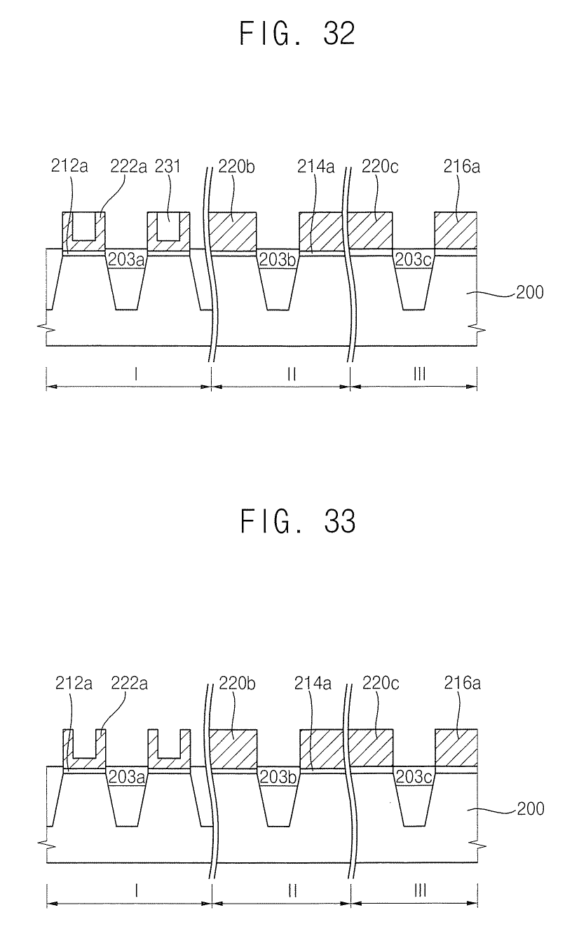

Referring to FIG. 32, the first to the third preliminary isolation layers 202a, 202b and 202c are partially removed to provide a first isolation layer 203a, a second isolation layer 203b and a third isolation layer 203c. The first to the third isolation layers 203a, 203b and 203c may be formed by a dry etching process. While partially etching the first to the third preliminary isolation layers 202a, 202b and 202c, the sacrificial layer pattern 231 may protect the floating gate 222a.

When the first to the third isolation layers 203a, 203b and 203c are formed on the substrate 200, the floating gate 222a, the second electrode 220b and the third electrode 220c are protruded from the firth to the third isolation layers 203a, 203b, and 203c, respectively. In example embodiments, the third isolation layer 203c may cover a sidewall of the third insulation layer pattern 216a whereas the third electrode 220c may exposed after the formation of the third isolation layer 203c. The first and the second isolation layers 203a and 203b may partially cover lower sidewalls of the floating gate 222a and the second electrode 220b because the first and the second insulation layer patterns 212a and 214a may be substantially thinner than the third insulation layer pattern 216a.

Referring to FIG. 33, the sacrificial layer pattern 231 is etched from the floating gate 222a, so that the floating gate 222a is completed in the cell area I. The sacrificial layer 231 may be removed by a wet etching process. When the floating gate 222a has the U shape, the semiconductor device including the floating gate 222a may have improved coupling ratio because an area between the floating gate 222a and a control gate is increased.

In example embodiments, adjacent floating gates may be separated from each other by the formation of the first isolation layer 203a, such that electrical interference between adjacent floating gates may be effectively prevented. Therefore, the semiconductor device may ensure more enhanced electrical characteristics and reliability.

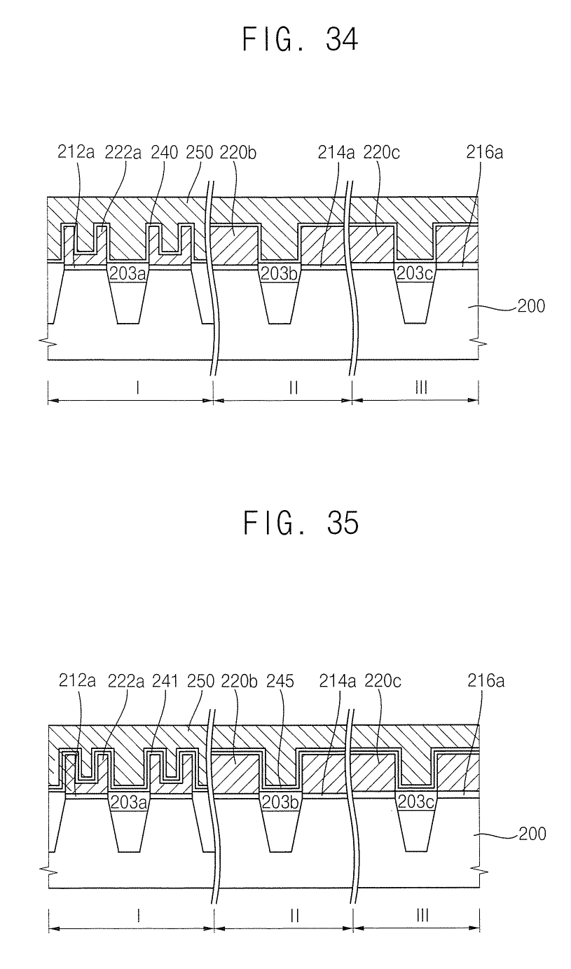

Referring to FIG. 34, a dielectric structure 240 is formed on the floating gate 222a, the second electrode 220b, the third electrode 220c, and the first to the third isolation layers 203a, 203b and 203c. Namely, the dielectric structure 240 may be conformally formed along the profiles of the floating gate 222a, the second electrode 220b and the third electrode 220c.

The dielectric structure 240 includes a metal oxide film and/or a metal oxynitride film. The metal oxide film or the metal oxynitride film may be obtained by an ALD process substantially the same as or substantially similar to the above-described ALD process. For example, the dielectric structure 240 may include a zirconium oxide film and/or a zirconium oxynitride film. Alternatively, the dielectric structure 240 may include at least one of an aluminum oxide film, a hafnium oxide film, a tantalum oxide film, a titanium oxide film, an aluminum oxynitride film, a hafnium oxynitride film, a tantalum oxynitride film and a titanium oxynitride film. The dielectric structure 240 may have a thickness of about 100 Å to about 300 Å.

The upper conductive layer 250 is formed on the dielectric structure 240. The upper conductive layer 250 may be formed using polysilicon, metal and/or metal compound. For example, the upper conductive layer 250 may include polysilicon doped with impurities, titanium, titanium nitride, tantalum, tantalum nitride, aluminum, titanium aluminum nitride, platinum, nickel, cobalt silicide, titanium silicide, tungsten, tungsten nitride, tungsten silicide, etc. These may be used alone or in a mixture thereof. Further, the upper conductive layer 250 may be formed by a sputtering process, a CVD process, an ALD process, a PECVD process, a PLD process, an evaporation process, etc

In example embodiments, a first portion of the upper conductive layer 250 in the cell area I may serve as the control gate, and a second portion of the upper conductive layer 250 in the low voltage transistor area II may serve as a first gate electrode of a lower voltage transistor. Additionally, a third portion of the upper conductive layer 250 in the high voltage area II may be used as a second gate electrode of a high voltage transistor.

In some example embodiments, the second and the third portions of the upper conductive layer 250 may be formed in the low and high voltage transistor areas II and III after removing portions of the dielectric structure 240 from the low and high voltage transistor areas II and III.

Since the floating gate 222a has the U shape and the dielectric structure 240 has good step coverage and improved leakage current characteristics, the semiconductor device may have enhanced electrical characteristics such improved reliability, constant threshold voltage, decreased leakage current, etc.

FIG. 35 is a cross sectional view illustrating a method of manufacturing a semiconductor device in accordance other example embodiments.

As illustrated in FIG. 35, a dielectric structure includes a metal oxide film 241 and a metal oxynitride film 245. That is, the dielectric structure includes the metal oxide film 241 and the metal oxynitride film 245 sequentially formed on the floating gate 222a, the second electrode 220b, the third electrode 220c, and the first to the third isolation layers 203a, 203b and 203c. Here, the metal film 241 and the metal oxynitride film 245 may be conformally formed along the profiles of the floating gate 222a, the second electrode 220b and the third electrode 220c.

The upper conductive layer 250 is provided on the dielectric structure having the metal oxide film 241 and the metal oxynitride film 245. The upper conductive layer 250 may fully fill up a gap between adjacent floating gates 222a, a gap between adjacent second electrodes 220b, and a gap between adjacent third electrodes 220c. The second electrode 220b in the low voltage transistor area II may serve as a gate electrode of a low voltage transistor, and the third electrode 220c in the high voltage transistor area III may serve as a gate electrode of a high voltage transistor. In this case, portions of the dielectric structure in the low and the high voltage transistor areas II and III may be removed before forming the upper conductive layer 250.

In example embodiments, the metal oxide film 241 and the metal oxynitride film 245 may be formed by ALD processes substantially the same as or substantially similar to the above-described ALD process. Thus, the metal oxide film 241 and the metal oxynitride film 245 may include zirconium oxide and zirconium oxynitride, respectively. Alternatively, the metal oxide film 241 may include aluminum oxide, hafnium oxide, tantalum oxide, titanium oxide, etc. Further, the metal oxynitride film 245 may include aluminum oxynitride, hafnium oxynitride, tantalum oxynitride, titanium oxynitride, etc. Here, the metal oxide film 241 may have a thickness of about 50 Å to about 200 Å, and the metal oxynitride film 245 may have a thickness of about 50 Å to about 100 Å.

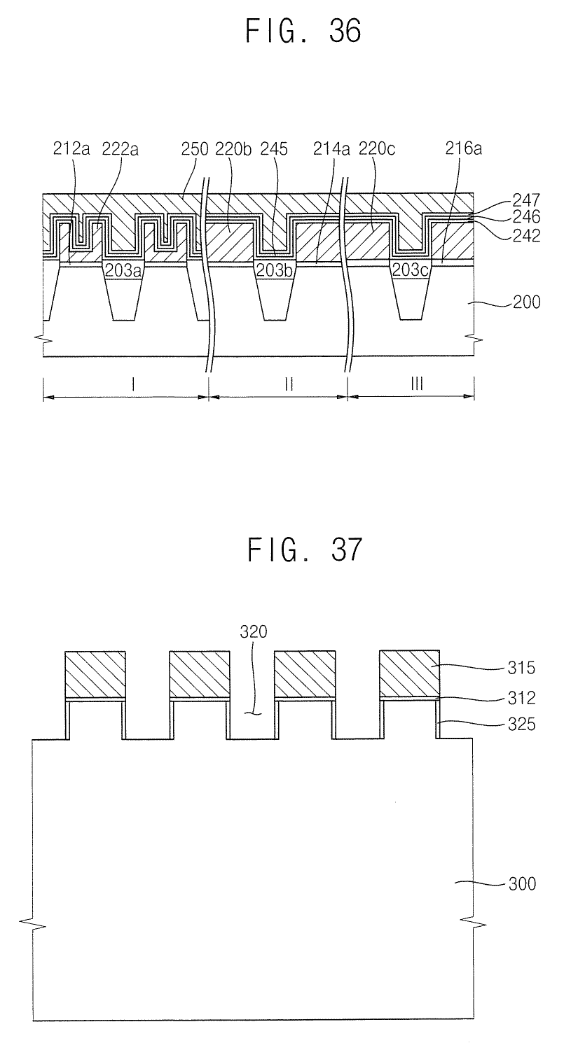

FIG. 36 is a cross sectional view illustrating a method of manufacturing a semiconductor device in accordance other example embodiments.

Referring to FIG. 36, a dielectric structure includes a first metal oxide film 242, a metal oxynitride film 246 and a second metal oxide film 247. Namely, the dielectric structure includes the first metal oxide film 242, the metal oxynitride film 246 and the second metal oxide film 247 successively stacked on the floating gate 222a, the second electrode 220b, the third electrode 220c, and the first to the third isolation layers 203a, 203b and 203c. The first metal oxide film 242, the metal oxynitride film 246 and the second metal oxide film 247 may be formed by processes substantially the same as or substantially similar to the above-described ALD process. For example, the first and the second metal oxide films 242 and 247 may include zirconium, and the metal oxynitride film 246 may include zirconium oxynitride. Further, each of the first and the second metal oxide films 242 and 247 may have a thickness of about 50 Å to about 100 Å, and the metal oxynitride film 246 may have a thickness of about 50 Å to about 100 Å.

The upper conductive layer 250 is provided on the dielectric structure having the first metal oxide film 242, the metal oxynitride film 246 and the second metal oxide film 247. The upper conductive layer 250 may fully fill up a gap between adjacent floating gates 222a, a gap between adjacent second electrodes 220b, and a gap between adjacent third electrodes 220c. The second electrode 220b in the low voltage transistor area II may serve as a gate electrode of a low voltage transistor, and the third electrode 220c in the high voltage transistor area III may serve as a gate electrode of a high voltage transistor. Here, portions of the dielectric structure in the low and high voltage transistor areas II and III may be removed before forming the upper conductive layer 250.

According to example embodiments, the dielectric structure including zirconium compound films may be obtained by varying the process temperature in the ALD process, such that the dielectric structure may have good step coverage and improved leakage current characteristics. Since the dielectric structure is used in the semiconductor device, the semiconductor device including the dielectric structure may ensure improved reliability and electrical characteristics.

FIGS. 37 to 47 are cross sectional views illustrating a method of manufacturing a semiconductor device in accordance with example embodiments.

Referring to FIG. 37, a pad oxide layer pattern 312 and a hard mask 315 are formed on a substrate 300. The pad oxide layer pattern 312 may include oxide such ac silicon oxide. The hard mask 315 may include nitride such as silicon nitride. The substrate 300 may include a semiconductor substrate, an SOI substrate, a GOI substrate, etc.

Using the hard mask 315 and the pad oxide layer pattern 312 as etching masks, the substrate 300 is partially etched along a first direction to form a first recess 320. The first recess 320 may be formed by anisotropically etching the substrate 300. The first recess 320 may have a depth in a range of about 10 Å to about 500 Å from an upper face of the substrate 300.

A protection layer 325 is formed on a sidewall of the first recess 320. The protection layer 325 may be formed by a CVD process or a thermal oxidation process. The protection layer 325 may include oxide such as silicon oxide.

Referring to FIG. 38, a portion of the substrate 300 exposed through the first recess 325 is etched along the first direction still using the hard mask 315 and the pad oxide layer pattern 312 as etching masks. Hence, a preliminary pillar structure 349 is provided on the substrate 300 in accordance with the formation of a second recess 330.

The pillar structure 349 may be formed by anisotropically etching the substrate 300. The second recess 330 may have a depth of about 500 Å to about 2,000 Å from the upper face of the substrate 300. Namely, the preliminary pillar structure 349 may have a height of about 500 Å to about 2,000 Å. Here, the protection layer 325 may cover an upper sidewall of the preliminary pillar structure 349.

Referring to FIG. 39, a portion of the substrate 300 is etched along a second direction substantially perpendicular to the first direction using the hard mask 315 and the protection layer 325 as etching masks, to thereby form a recess structure 335. The recess structure 335 may be formed by a wet etching process. When the recess structure 335 is provided, a pillar structure 350 is formed on the substrate 300. For example, the pillar structure 350 may be formed by horizontally etching a sidewall of the second recess 330. Hence, the recess structure 330 may have a width substantially larger that that of the second recess 330.

In example embodiments, the pillar structure 350 includes an upper portion 350b, a central portion 350a, and a lower portion 350a. The upper portion 350b may have a width substantially larger than the central portion 350b. The lower portion of the pillar structure 350 may have a width substantially similar to that of the upper portion 350b. For example, the pillar structure 350 may have an I shape.

A metal oxide layer 340 is formed on a sidewall of the pillar structure 350 or the recess structure 330. The metal oxide layer 340 may be formed through an ALD process substantially the same as or substantially similar to the above-described ALD process. For example, the metal oxide layer 340 may include zirconium oxide, hafnium oxide, aluminum oxide, tantalum oxide, titanium oxide, etc. Thus, the metal oxide layer 340 may be uniformly formed on the sidewall of the pillar 350.

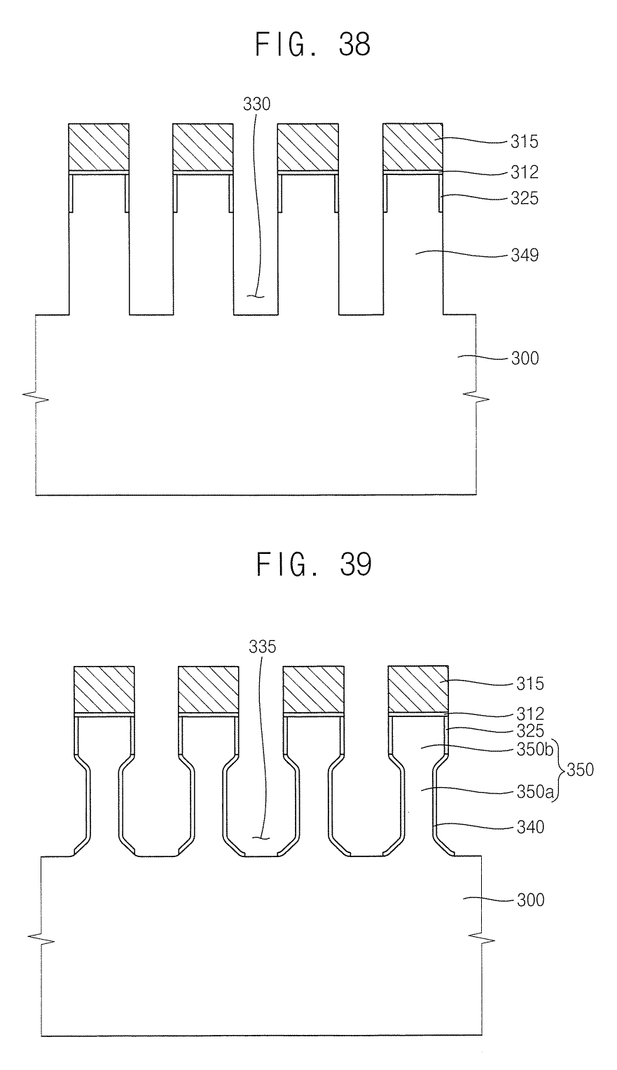

Referring to FIG. 40, a metal oxynitride layer 345 is formed on the metal oxide layer 340. The metal oxynitride layer 345 may also be formed through a process substantially the same as or substantially similar to the above-described ALD process. For example, the metal oxynitride layer 345 may include zirconium oxynitride, aluminum oxynitride, hafnium oxynitride, tantalum oxynitride, titanium oxynitride, etc. The metal oxynitride layer 345 may be conformally formed on the metal oxide layer 340 along the profiles of the pillar structure 350 and the hard mask 315.

When the metal oxynitride layer 345 is formed on the metal oxide layer 340, a gate insulation layer is provided on the sidewall of the pillar structure 350. The gate insulation layer may enclose the pillar structure 350. Here, a portion the gate insulation layer covering the hard mask 315 may be removed after forming the metal oxynitride layer 345.

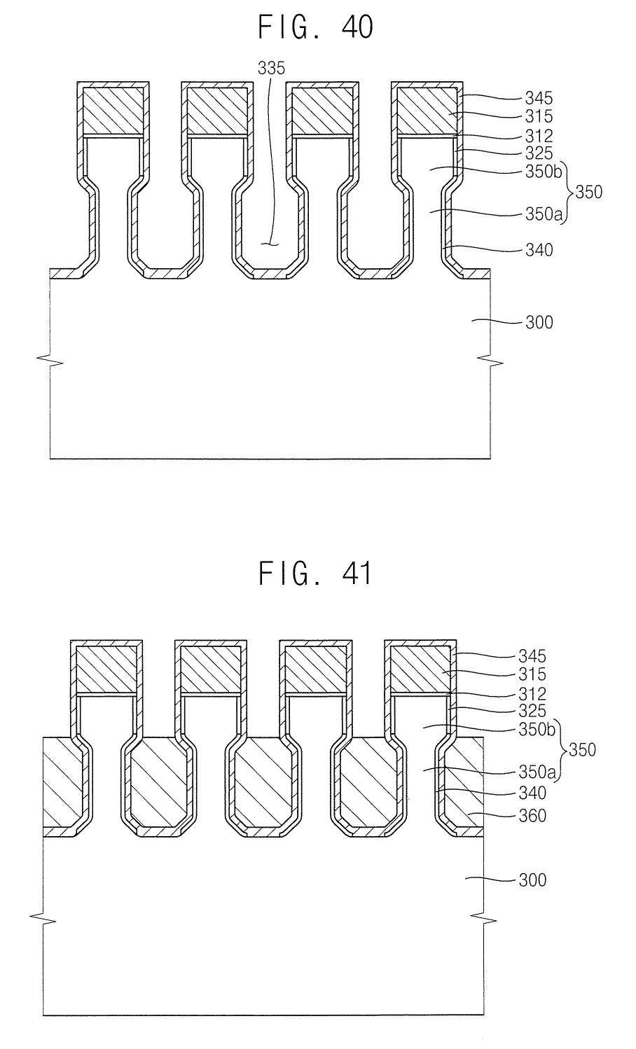

Referring to FIG. 41, a gate electrode layer 360 is formed on the substrate 300 to partially fill up the recess structure 335. The gate electrode layer 360 may be formed using polysilicon, metal and/or metal compound by a sputtering process, a CVD process, an ALD process, a PECVD process, a PLD process, an evaporation process, etc. For example, the gate electrode layer 360 may include polysilicon doped with impurities, titanium, tungsten, aluminum, tantalum, platinum, nickel, titanium nitride, tungsten nitride, tantalum nitride, aluminum nitride, cobalt silicide, titanium silicide, nickel silicide, etc. These may be used alone or in a mixture thereof.

In example embodiments, the gate electrode layer 360 may partially enclose the pillar 350 by interposing the gate insulation layer therebetween. For example, the gate electrode layer 360 may cover the lower portion and the central portion 350a of the pillar structure 350. Here, the upper portion of the pillar structure 350 may be partially covered with the gate electrode layer 360. The gate electrode layer 360 may have a height substantially smaller than that of the pillar structure 350.

Referring to FIG. 42, a buffer layer 370 is formed on the gate electrode layer 360 to cover the resultant structure exposed by the gate electrode layer 360. That is, the buffer layer 370 may cover the gate insulation layer positioned on the upper portion of the pillar structure 350 and the hard mask 315. Further, the buffer layer 370 may have a thickness sufficiently filling up a gap between adjacent pillars.

The buffer layer 370 may be formed using oxide by a CVD process, a PECVD process, a spin coating process, an HDP-CVD process, etc. For example, the buffer layer 370 may be formed using FOX, USG, SOG, TOSZ, TEOS, PE-TEOS, HDP-CVD oxide, etc.

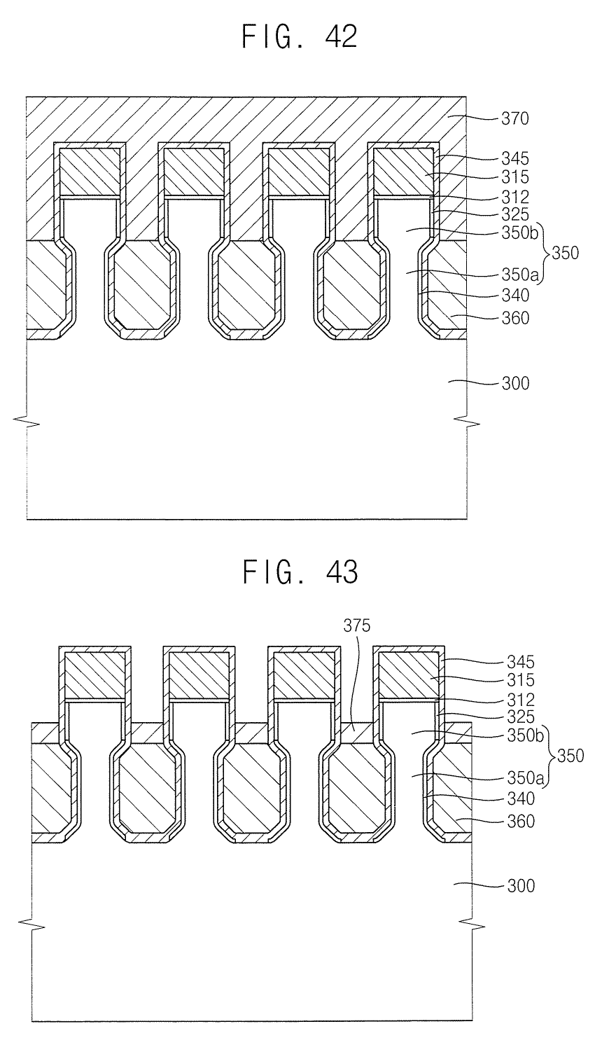

Referring to FIG. 43, the buffer layer 370 is etched to form a buffer layer pattern 375 is formed on the gate electrode layer 360 between adjacent pillar structures 350. The buffer layer pattern 375 may be formed by a set etching process or a dry etching process. The buffer layer pattern 375 may protect the gate electrode layer 360 in successive etching processes.

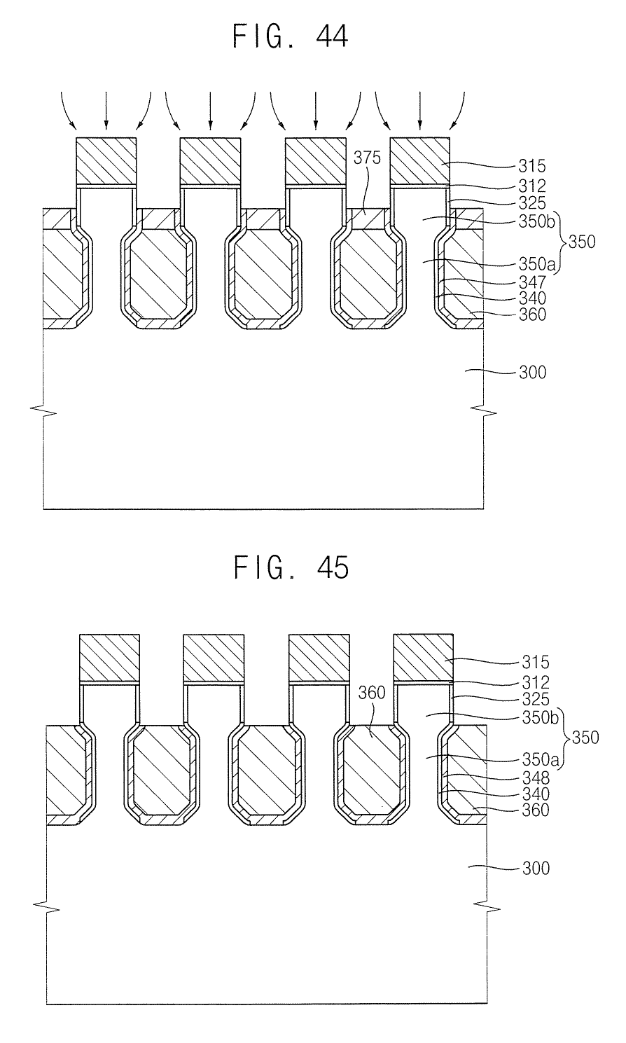

Referring to FIG. 44, the metal oxynitride layer 345 positioned on the hard mask 315 and the upper portion 350b of the pillar structure 350 is removed. For example, the metal oxynitride layer 345 may be partially removed by an etching solution including phosphoric acid when the metal oxynitride layer 345 is etched by a wet etching process. While partially etching the metal oxynitride layer 345, the buffer layer pattern 375 may effectively protect the gate electrode layer 360.

Referring to FIG. 45, the buffer layer pattern 375 is removed from the gate electrode layer 360, so that the gate electrode layer 360 is exposed between adjacent pillar structures 350. After removing the metal oxynitride layer 345 and the buffer layer pattern 375, the upper portion 350b of the pillar structure 350 may be partially exposed. The buffer layer pattern 375 may be etched using an etching solution including hydrogen fluoride (HF) or an etching gas containing hydrogen fluoride when the buffer layer pattern 375 includes oxide.

Referring to FIG. 46, the exposed portion of the gate electrode layer 360 is etched to form a gate electrode 365 on the central portion 350a and the lower portion of the pillar structure 350. While forming the gate electrode 365, the gate insulation layer is also partially etched to form a gate insulation layer pattern on the central portion 350a and the lower portion of the pillar structure 350. Thus, the gate electrode 365 may enclose the central portion 350a and the lower portion of the pillar structure 350 by interposing the gate insulation pattern. The gate insulation layer pattern includes a metal oxide layer pattern 341 and a metal oxynitride layer pattern 348 sequentially formed on the central portion 350a and the lower portion of the pillar structure 350.

When the gate electrode 365 and the gate insulation layer pattern are formed, a third recess 338 exposing a portion of the substrate 300 between adjacent pillar structures 350 is provided. A first impurity region 380 is formed at the exposed portion of the substrate 300 by implanting impurities into the exposed portion of the substrate 300 between adjacent pillar structures 350. The hard mask 315 may serve as an implantation mask for forming the first impurity region 380.

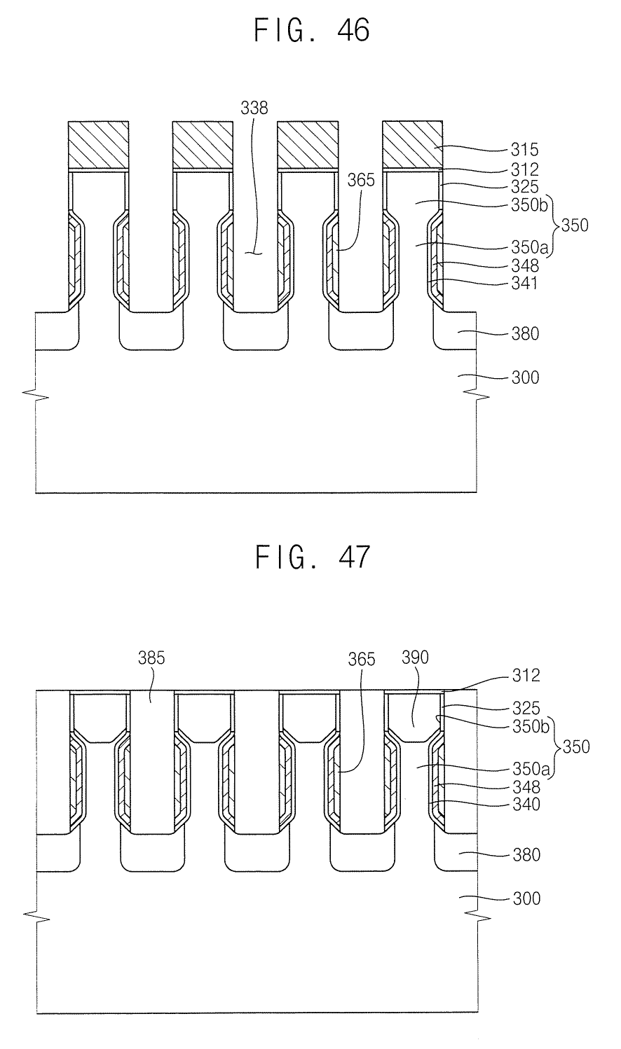

Referring to FIG. 47, an insulation layer 385 is formed on the first impurity region 380 and the pillar structure 350 after removing the hard mask 315 from the upper portion 350b of the pillar structure 350. The insulation layer 385 may fully fill up the third recess 338. Then, the insulation layer 385 may be partially removed until the pad oxide layer pattern 312 is exposed by a CMP process and/or an etch-back process.

The insulation layer 385 may be formed by a CVD process, a PECVD process, a spin coating process, an HDP-CVD process, etc. The insulation layer 385 may include oxide such as silicon oxide. For example, the insulation layer 385 may be formed using SOG, USG, FOX, TOSZ, TEOS, PE-TEOS, BPSG, PSG, HDP-CVD oxide, etc.

A second impurity region 390 is formed at the upper portion 350b of the pillar structure 350 by implanting impurities into the upper portion 350b of the pillar structure 350. The second impurity region 390 may be formed by doping the impunities through the pad oxide layer pattern 312.

Because the gate insulation layer pattern includes the metal oxide layer pattern 341 and the metal oxynitride layer pattern 348 formed by the ALD process while changing the process temperature of the ALD process, the semiconductor device including the gate insulation layer may have desired threshold voltage and reduced leakage current, thereby improving the electrical characteristics of the semiconductor device.

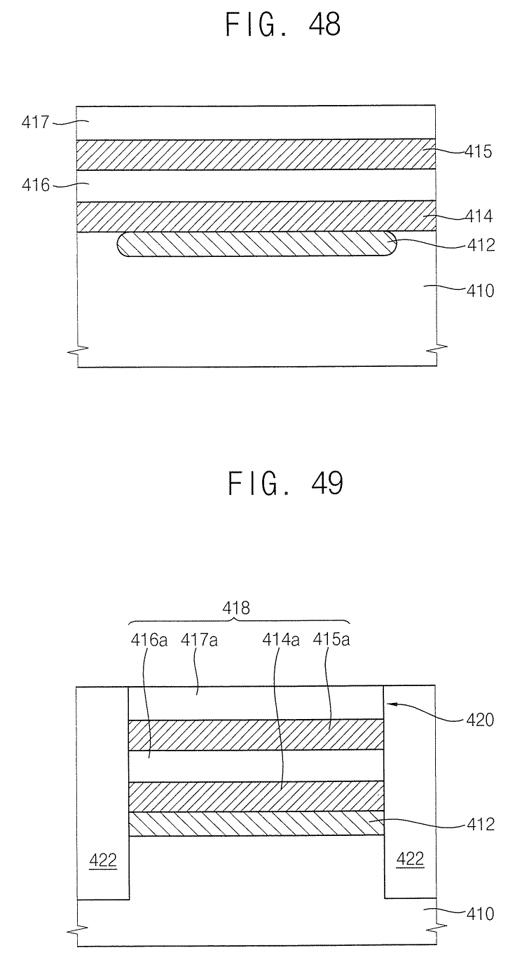

FIGS. 48 to 61 are cross-sectional views illustrating a method of manufacturing a semiconductor device in accordance with example embodiments.

Referring to FIG. 48, a preliminary first impurity region 412 is formed at a portion of a substrate 410. The substrate 410 may include a semiconductor substrate such as a silicon substrate, a germanium substrate, a silicon-germanium substrate, etc. The preliminary first impurity region 412 may have a relatively high impurity concentration. The preliminary first impurity region 412 may be formed by doping first impurities into the portion of the substrate 410. The preliminary first impurity region 412 may ensure improved channel separation effect of transistors provided on the substrate 410.

A plurality of first semiconductor layer 414 and 415 and a plurality of second semiconductor layer 416 and 417 are formed on the substrate 410 having the preliminary first impurity region 412. The first and the second semiconductor layers 414, 415, 416 and 417 are alternately formed on the substrate 410. The first and the second semiconductor layers 414, 415, 416 and 417 may be formed by selective epitaxial growth processes. Each of the first and the second semiconductor layers 414, 415, 416 and 417 may have a thickness of about 300 Å to about 500 Å.

In example embodiments, each of the first semiconductor layers 414 and 415 may include single crystalline silicon, single crystalline germanium, silicon-germanium, etc. Further, each of the second semiconductor layers 416 and 417 may also include single crystalline silicon, single crystalline germanium, silicon-germanium, etc. For example, the first semiconductor layers 414 and 415 may include silicon-germanium, and the second semiconductor layers 416 and 417 may include single crystalline silicon.

Referring to FIG. 49, after a mask (not illustrated) is provided on the second semiconductor layer 417, the first and the second semiconductor layers 414, 415, 416 and 417 and the substrate 410 are partially etched to form a preliminary active region 418 and a trench (not illustrated). The preliminary active region 418 and the trench may be formed by anisotropic etching process. The preliminary active region 418 is positioned on the first impurity region 412 of the substrate 410, and the trench is formed on the substrate 410.

In example embodiments, the preliminary active region 418 includes a plurality of preliminary first semiconductor layer patterns 414a and 415a and a plurality of preliminary second semiconductor layer patterns 416a and 417a. Here, the preliminary first and the preliminary second semiconductor layer patterns 414a, 415a, 416a and 417a may be alternately disposed on the substrate 410.

An isolation layer 422 is formed in the trench to enclose a sidewall of the preliminary active region 418. The isolation layer 422 may be formed by a CVD process, a spin coating process, an HDP-CVD process, a PECVD process, etc. Further, the isolation layer 422 may include oxide such as silicon oxide. For example, the isolation layer 422 may be formed using USG, SOG, FOX, TOSZ, TEOS, PE-TEOS, HDP-CVD oxide, etc.

In example embodiments, the isolation layer 422 may isolate one preliminary active region 418 from another preliminary active region 418. That is, adjacent preliminary active regions may be separated by the isolation layer 422. The preliminary active region 418 isolated by the isolation layer 422 may have an island structure.

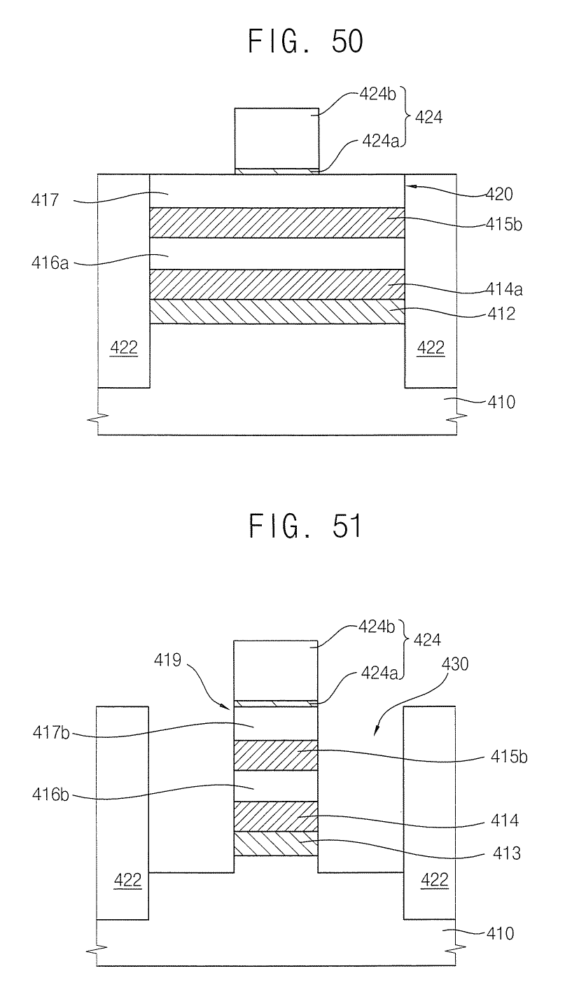

Referring to FIG. 50, a dummy gate structure 424 is formed on the preliminary active region 418. The dummy gate structure may include a first mask pattern 424a and a second mask pattern 424b sequentially formed on the preliminary active region 418. The first mask pattern 424a may be formed using oxide whereas the second mask pattern 424b may be formed using nitride. For example, the first mask pattern 424a and the second mask pattern 424b may include silicon oxide and silicon nitride, respectively.

In some example embodiments, the first mask pattern 424a may include oxide or nitride, and the second mask pattern 424b may include conductive material. For example, the second mask pattern 424b may be formed using polysilicon, metal and/or metal compound.

Referring to FIG. 51, the preliminary active region 418 and the substrate 410 are partially etched using the dummy gate structure 424 as an etching mask. Thus, an active region 419 is formed on the substrate 410 and an opening 430 is provided between the active region 419 and the isolation layer 422. Additionally, a first impurity region 413 is formed between the substrate 410 and the active region 419 by partially etching the preliminary first impurity region 412. The active region 419 and the isolation layer 430 may be obtained by an anisotropic etching process.

Because the substrate 410 having the first impurity region 412 is partially etched, the opening 430 exposes a portion of the substrate 410 adjacent to the first impurity region 413.

The active region 419 includes a plurality of first semiconductor layer patterns 414b and 415b and a plurality of second semiconductor layer patterns 416b and 417b. The first and the second semiconductor layer patterns 414b, 415b, 416b and 417b are obtained by patterning the preliminary first and the preliminary second semiconductor layer patterns 414a, 415a, 416a and 417a, respectively.

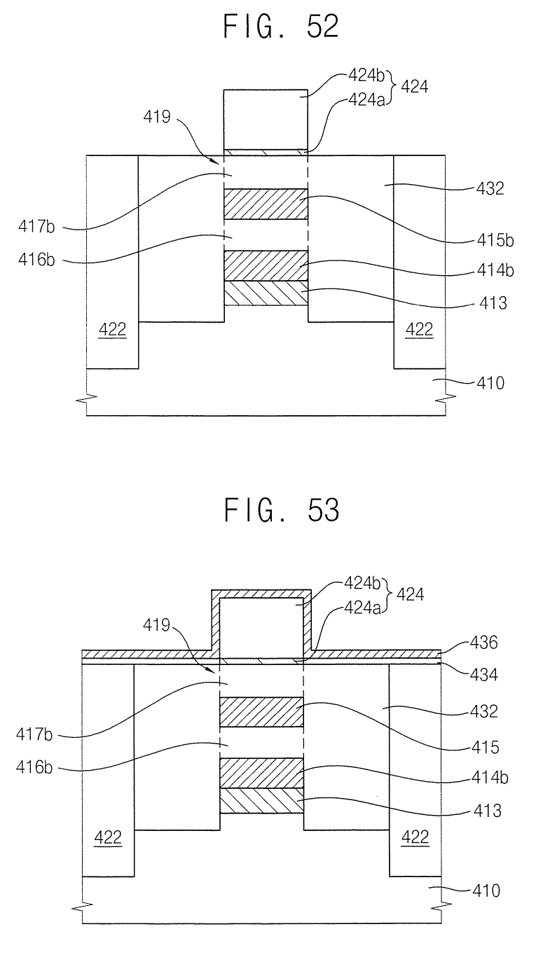

Referring to FIG. 52, a third semiconductor layer 432 is formed on the substrate 410 to fill up the opening 430. The third semiconductor layer 432 may be formed by a selective epitaxial growth process. Further, the third semiconductor layer 432 may include single crystalline silicon, single crystalline germanium, silicon-germanium, etc. For example, the third semiconductor layer 432 may include single crystalline silicon when the substrate 410 includes silicon.

In example embodiments, the third semiconductor layer 432 may make contact with the isolation layer 422 and the active region 419 because the third semiconductor layer 432 fully fills up the opening 430. The third semiconductor layer 432 may serve as source/drain of a transistor.

Referring to FIG. 53, a pad oxide layer 434 is formed on the third semiconductor layer 432 and the isolation layer 422. The pad oxide layer 434 may be formed using oxide by a CVD process or a thermal oxidation process. For example, the pad oxide layer 434 may include silicon oxide. The pad oxide layer 434 may not cover the dummy gate structure 424.

An etch stop layer 436 is formed on the pad oxide layer 434 and the dummy gate structure 424. The etch stop layer 436 may be conformally formed along the profile of the dummy gate structure 424. The etch stop layer 436 may be formed using a material that has an etching selectivity relative to the active region 419 and the third semiconductor layer 432. For example, the etch stop layer 436 may include nitride such as silicon nitride or oxynitride like silicon oxynitride.

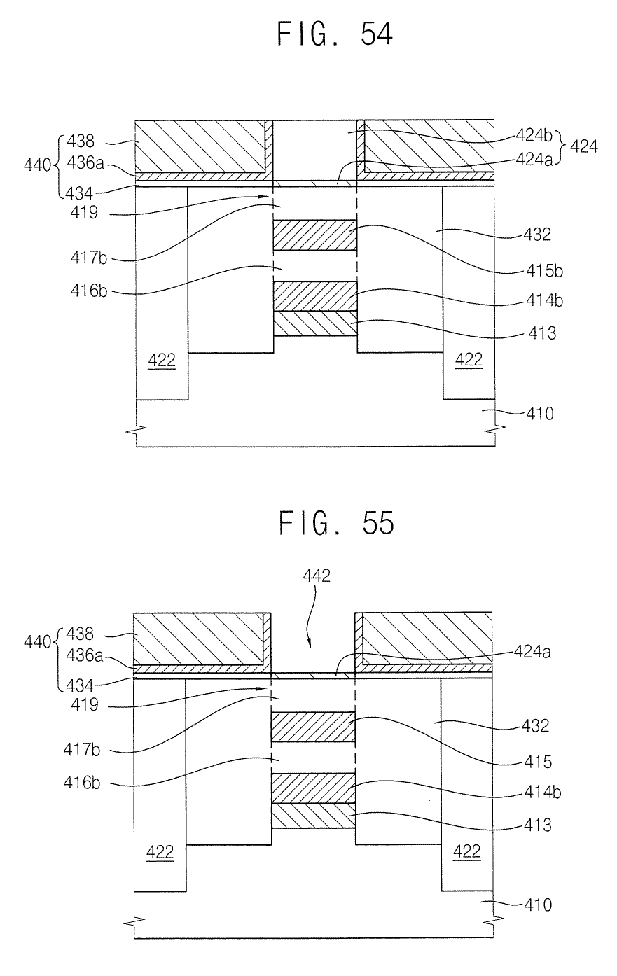

Referring to FIG. 54, a polysilicon layer (not illustrated) is formed on the etch stop layer 436 to cover the dummy gate structure 424. The polysilicon layer and the etch stop layer 436 are partially removed until the dummy gate structure 424 is exposed. Hence, a mask structure 440 is provided adjacent to the dummy gate structure 424.

The mask structure 440 includes a polysilicon layer pattern 438, an etch stop layer pattern 436a and the pad oxide layer 434. The dummy gate structure 424 may be enclosed by the mask structure 440 after forming the mask structure 440 on the third semiconductor layer 432 and the isolation layer 422.

Referring to FIG. 55, the dummy gate structure 424 is partially removed from the active region 419 using the mask structure 440 as an etching mask. Namely, the second mask pattern 424b of the dummy gate structure 424 is etched from the first mask pattern 424a. When the dummy gate structure 424 is partially etched, a gate trench 442 is provided on the first mask pattern 424a adjacent to the mask structure 440.

In example embodiments, by-products remaining on the first mask pattern 424a or a native oxide film generated on the first mask pattern 424a may be removed through a cleaning process, to thereby enhancing electrical characteristic of the transistor. That is, a bottom and a sidewall of the gate trench 442 may be exposed to the cleaning process.

The first mask pattern 424a exposed through the gate trench 442 is removed from the active region 419. When the first mask pattern 424a includes oxide, the first mask pattern 424a may be removed through the cleaning process or an etching process using an etchant containing hydrogen fluoride.

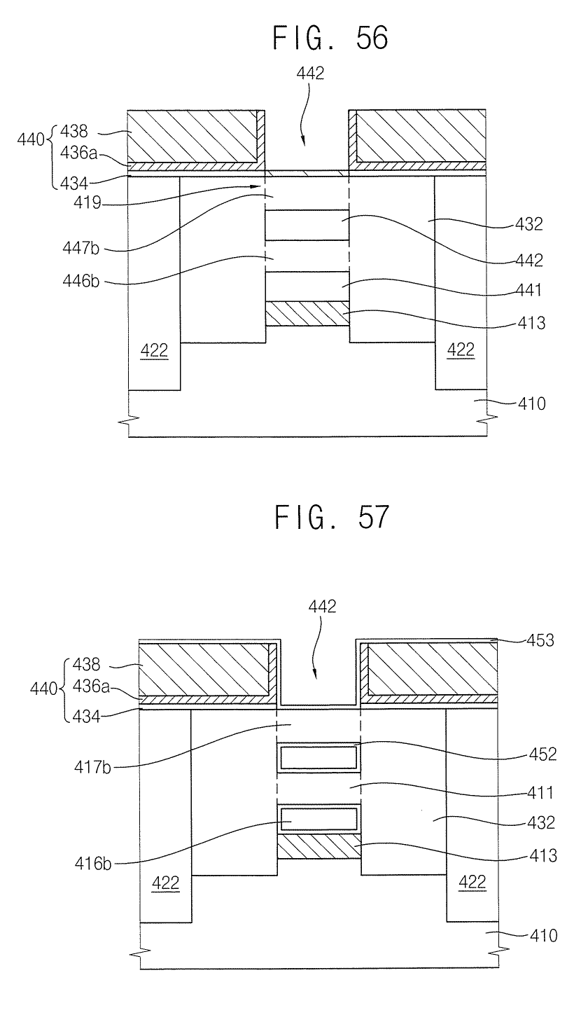

Referring to FIG. 56, the first semiconductor layer patterns 414b and 415b are removed to form a plurality of tunnel structures 441 and 442 between adjacent second semiconductor layer patterns 416b and 417b. That is, the tunnel structures 441 and 442 may pass through the active regions 419.

In example embodiments, the tunnel structures 441 and 442 may be formed using an etching solution that has an etching selectivity between the first semiconductor layer patterns 414b and 415b and the second semiconductor layer patterns 416b and 417b.

Channel impurities are doped into the second semiconductor layer patterns 416b and 417b. The channel impurities may be doped into the second semiconductor layer patterns 416b and 417b by a plasma ion implantation process.

Referring to FIG. 57, first dielectric structures 452 and a second dielectric structure 453 are formed by processes substantially the same as or substantially similar to the above-described ALD process. The first dielectric structures 452 are formed insides of the tunnel structures 441 and 442, respectively. The second dielectric structure 453 is positioned on the active region 419 and the mask structure 440. Here, the second dielectric structure 453 may be conformally formed along the profile of the mask structure 440.

Each of the first dielectric structures 452 may be uniformly formed on the entire inside of each of the tunnel structures 441 and 442. Since the first dielectric structures 452 have good step coverage as described above, the first dielectric structures 452 may be conformally formed on the insides of the tunnel structures 441 and 442.

In example embodiments, each of the first and the second dielectric structures 452 and 453 may include at least one metal oxide film and/or at least one oxynitride film. For example, each of the first and the second dielectric structures 452 and 453 may have at least one zirconium oxide film and/or at least one zirconium oxynitride film.

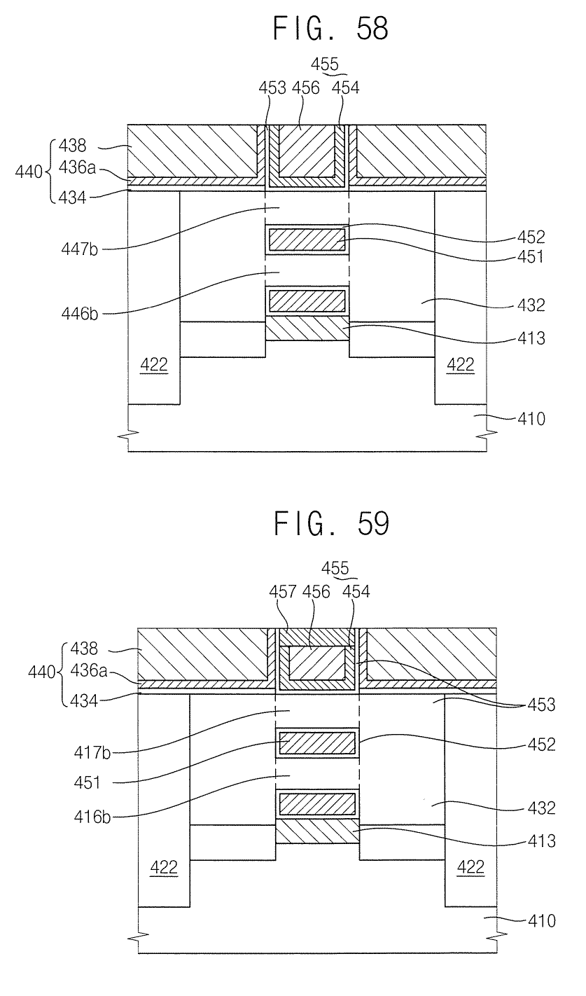

Referring to FIG. 58, a portion of the second dielectric structure 453 on the mask structure 440 is removed, and then first gate structures 451 and a second gate structure 455 are formed. The first gate structures 451 may be formed to fill up the tunnel structures 441 and 442. The second gate structure 455 is formed on the second dielectric structure 453 between adjacent mask structures. The second gate structure 455 may fill up the gate trench 442.

The first gate structures 451 may include polysilicon metal and/or metal compound. For example, the first gate structure 451 may include polysilicon doped with impurities, tungsten, titanium, aluminum, tantalum, tungsten nitride, titanium nitride, aluminum nitride, tantalum nitride, etc. These may be used alone or in a mixture thereof. Further, the first gate structures 451 may be formed by a CVD process, an ALD process, a PECVD process, a PLD process, an evaporation process, etc.

The second gate structure 455 includes a first gate electrode 454 and a second gate electrode 456. The first gate electrode 454 may be formed on the active region 419 and the sidewall of the mask structure 440. The second gate electrode 456 may fill up the gate trench 442. Each of the first and the second gate electrodes 454 and 456 may be formed using polysilicon metal and/or metal compound. For example, each of the first and the second gate electrodes 454 and 456 may include polysilicon doped with impurities, tungsten, titanium, aluminum, tantalum, tungsten nitride, titanium nitride, aluminum nitride, tantalum nitride, etc. These may be used alone or in a mixture thereof. Additionally, the second gate structures 455 may also be formed by a CVD process, an ALD process, a PECVD process, a PLD process, an evaporation process, etc.

Referring to FIG. 59, a gate mask 457 is formed on the second gate structure 455. The gate mask 457 may be formed using nitride or oxynitride. For example, the gate mask 457 may include silicon oxide or silicon oxynitride obtained by a CVD process, a PECVD process, an LPCVD process, etc.

In example embodiments, the second gate structure 455 may be partially removed before forming the gate mask 457. Alternatively, the gate mask 457 may be omitted to simplify processes for forming the semiconductor device. The second dielectric structure 453 is positioned on a sidewall of the second gate structure 455.

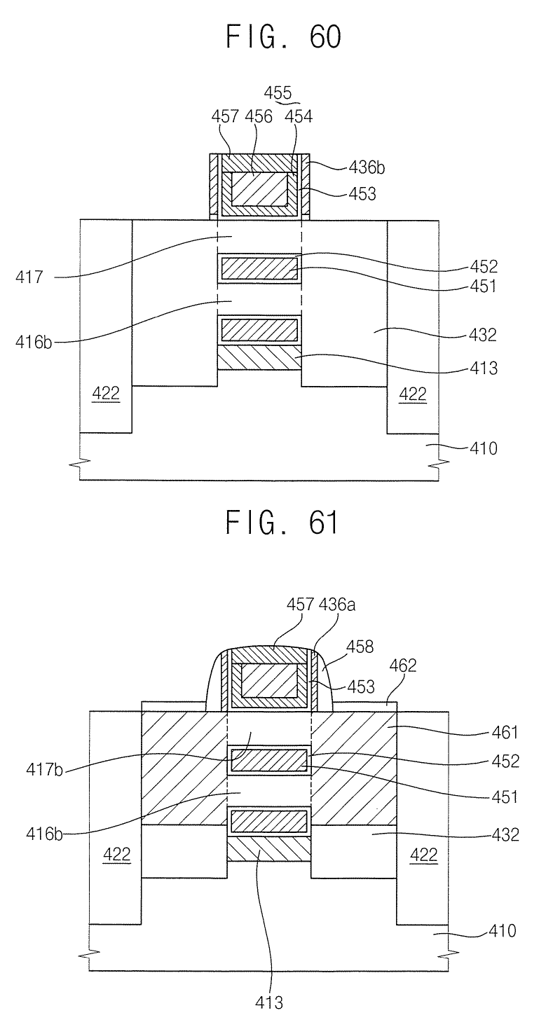

Referring to FIG. 60, a polysilicon layer pattern 438 and a portion of the etch stop layer pattern 436a are removed to provide a second etch stop layer pattern 438b on the second dielectric structure 453. When the second etch stop layer pattern 438b is formed, the third semiconductor layer 432 adjacent to the second gate structure 455 is exposed.

Referring to FIG. 61, second impurities are doped into the third semiconductor layer 432 so that source/drain regions 461 are formed adjacent to the second gate structure 455. A spacer 458 is formed on the sidewall of the second gate electrode 455, and then a metal silicide layer 462 is formed on the source/drain regions 461.

The spacer 458 may be formed using nitride and the metal silicide layer 462 may include cobalt silicide, titanium silicide, nickel silicide, zirconium silicide, tungsten silicide, etc. In example embodiments, the spacer 458 may be formed by etching a spacer formation layer covering the second gate electrode 455. The metal silicide layer 462 may be formed by performing a silicidation process about a metal layer on the source/drain regions 461.

FIG. 62 is a block diagram illustrating a memory system in accordance with example embodiments.

Referring to FIG. 62, the memory system includes a memory controller 620 and a memory device 610 electrically connected to the memory controller 620. The memory device 610 may include a capacitor or a flash memory device having a dielectric structure formed through the above-described ALD process. Alternatively, the memory device 610 may include other non-volatile semiconductor memory devices or volatile semiconductor devices such as DRAM devices, SRAM devices, etc.

The memory controller 620 may provide an input signal into the memory device 610 to control the reading and the erasing operations of the memory device 610. For example, various signals such as command (CMD), address (ADD), input/output data (DQ) or a high-voltage (VPP) signal may be applied to the memory controller 620. The memory controller 620 may control the memory device 610 based on the applied various signals. The memory system may be employed in various electronic apparatuses such as a cellular phone, a portable multimedia player, a digital camera, etc.

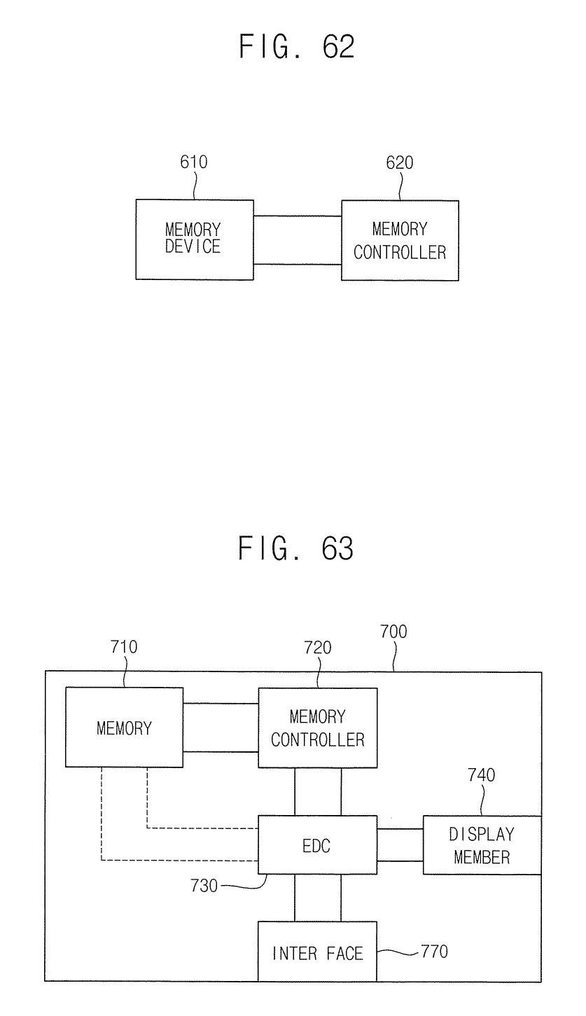

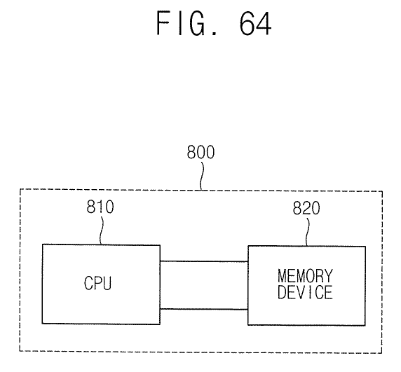

FIG. 63 is a block diagram illustrating another memory system in accordance with example embodiments.

Referring to FIG. 63, the memory system is used in a portable electronic apparatus 700. The portable electronic apparatus 700 may include an MP3 player, a portable video player, a portable multimedia player, a digital camera, etc. The memory system in the portable electronic apparatus 700 includes a memory device 710 and a memory controller 720. Further, the memory system includes an encoder/decoder (EDC) 730, a display member 740 and an interface 770. The memory device 710 may include a flash memory device having a dielectric structure. Alternatively, the memory device 710 may include a volatile semiconductor device including a capacitor having a dielectric structure. Here, the dielectric structure may be obtained through the above-described ALDD process.

The EDC 730 may input/output data such as audio data or video data into/from the memory device 710 through the memory controller 720. Alternatively, the data may be directly inputted from the EDC 730 into the memory device 710 or may be directly outputted from the memory device 710 into the EDC 730.

The EDC 730 may encode of the data stored in the memory device 710. For example, the EDS 730 may carry out encoding of MP3 files to store the audio data into the memory device 710. Alternatively, the EDC 730 may encode MPEG files to store the video data into the memory device 710. Further, the EDS 730 may include a compound encoder for encoding different file types of various data. For example, the EDC 730 may include an MP3 encoder for the audio data and an MPEG encoder for the video data.

The EDC 730 may decode the data from the memory device 710. For example, the EDC 730 may perform decoding of the MP3 files based on the audio data stored in the memory device 710. Alternatively, the EDC 730 may execute decoding of MPEG files from the video data stored in the memory device 710. Thus, the EDC 730 may include an MP3 decoder for the audio data and an MPEG decoder for the video data.

In example embodiments, the EDC 730 may include a decoder without an encoder. For example, encoded data may be inputted into the EDC 730, and then the encoded data may be directly stored into the memory device 710 or may be stored into the memory device 710 through the memory controller 720 when the EDC 730 has the decoder only.

In example embodiments, the EDC 730 may receive data for encoding or encoded data through the interface 770. The interface 770 may meet a predetermined reference such as a fire wire or a USB. For example, the interface 770 may include a fire wire interface or a USB interface. Further, the data stored in the memory device 710 may be outputted through the interface 770.

The display member 740 may display the data outputted from the memory device 710 or the decoded data from the EDC 730. For example, the display member 740 may include a speaker jack to output the audio data and/or a display screen to display the video data.

FIG. 64 is a block diagram illustrating still another memory system in accordance with example embodiments.

Referring to FIG. 64, the memory system includes a memory device 820 and a central processing unit (CPU) 810 in a computer system 800. The memory device 820 is electrically connected to the CPU 810. For example, the computer system 800 may include a personal computer, a personal data assistant, a note book computer, etc. The memory device 820 may be directly connected to the CPU 810 or may be electrically connected to the CPU 810 through a BUS.

According to example embodiments, zirconium compound films may have good step coverage and improved leakage current characteristics because the zirconium compound films may be obtained by varying the process temperature in the ALD process. When the zirconium compound films is used in a semiconductor device as a dielectric layer, a gate insulation layer or a tunnel insulation layer, the zirconium compound films may be uniformed formed on a predetermined structure even though the predetermined structure has high aspect ratio. Additionally, the semiconductor device including the zirconium compound films may ensure improved reliability the electrical characteristics. Furthermore, an apparatus for performing the ALD process includes a substrate holder and a heating block, a plurality of zirconium compound films may be simultaneously provided on a plurality of substrates. Thus, the yield of manufacturing semiconductor devices may also be greatly improved.

The foregoing is illustrative of example embodiments, and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed example embodiments, as well as other example embodiments, are intended to be included within the scope of the appended claims. The invention is defined by the following claims, with equivalents of the claims to be included therein.

1. A method of manufacturing a semiconductor device, comprising:
forming an absorption layer on a surface of a substrate by exposing the surface to a first reaction gas at a first temperature; and
forming a metal oxide layer on the surface of the substrate by exposing the absorption layer to a second reaction gas at a second temperature.

2. The method of claim 1, wherein said forming an absorption layer is performed within a reaction chamber; and wherein said forming a metal oxide layer is preceded by a step of purging the first reaction gas from the reaction chamber.

3. The method of claim 1, wherein the first reaction gas comprises a precursor containing zirconium and the second reaction gas comprises an oxidizing agent.

4. The method of claim 3, wherein the precursor comprises tetrakis(ethylmethylamino)zirconium and the oxidizing agent comprises an oxygen gas, an ozone gas and/or water vapor.

5. The method of claim 1, wherein the second temperature is greater than the first temperature.

6. The method of claim 5, wherein the first temperature is in a range from about 240° C. to about 260° C. and the second temperature is in a range from about 265° C. to about 285° C.

7. The method of claim 1, further comprising:
converting at least a portion of the metal oxide layer into a metal oxynitride layer by exposing the metal oxide layer to a third reaction gas; and
exposing the metal oxynitride layer to a plasma.

8. The method of claim 1, further comprising:
converting at least a portion of the metal oxide layer into a metal oxynitride layer by exposing the metal oxide layer to a third reaction gas comprising a nitrifying agent; and
exposing the metal oxynitride layer to a plasma comprising nitrogen.

9. The method of claim 8, wherein the nitrifying agent is selected from a group consisting of nitrogen monoxide, nitrogen dioxide and ammonia (NH₃).

10. The method of claim 1, wherein the surface of the substrate is a surface of a cylindrical capacitor electrode; and wherein said forming a metal oxide layer is followed by a step of forming an upper capacitor electrode on the metal oxide layer.

11. The method of claim 1, wherein the surface of the substrate is an upper surface of a floating gate electrode of a memory device; and wherein said forming a metal oxide layer is followed by a step of forming a control gate electrode on the metal oxide layer, opposite the upper surface of the floating gate electrode.

12. The method of claim 8, further comprising forming a second metal oxide layer on the metal oxynitride layer by exposing the metal oxynitride layer to the second reaction gas.

13. The method of claim 12, further comprising converting at least a portion of the second metal oxide layer into a second metal oxynitride layer by exposing the second metal oxide layer to the third reaction gas and then exposing the second metal oxynitride layer to the plasma.

14. The method of claim 13, wherein the first temperature is in a range from about 240° C. to about 260° C. and the second temperature is in a range from about 265° C. to about 285° C.

15. A method of manufacturing an integrated circuit capacitor, comprising:
forming a lower capacitor electrode on a substrate;
forming a first absorption layer on a surface of the lower capacitor electrode by exposing the surface to a reaction gas comprising zirconium;
converting at least a portion of the first absorption layer to a zirconium oxide layer by oxidizing the first absorption layer;
converting at least a portion of the zirconium oxide layer to a zirconium oxynitride layer by exposing the zirconium oxide layer to a reaction gas comprising a nitrifying agent;
exposing the zirconium oxynitride layer to a plasma comprising nitrogen; and
forming an upper capacitor electrode on the zirconium oxynitride layer.

16. The method of claim 15, further comprising:
forming a second absorption layer on a surface of the zirconium oxynitride layer by exposing the surface of the zirconium oxynitride layer to a reaction gas comprising zirconium; and
converting at least a portion of the second absorption layer to a second zirconium oxide layer by oxidizing the second absorption layer; and
converting at least a portion of the second zirconium oxide layer to a second zirconium oxynitride layer by exposing the second zirconium oxide layer to a reaction gas comprising a nitrifying agent.

17. A method of manufacturing a semiconductor device, comprising:
loading a substrate into a reaction chamber;
forming an absorption layer on the substrate by providing a first reaction gas onto the substrate at a first temperature;
purging a remaining first reaction gas from the substrate;
forming a metal oxide layer on the substrate by providing a second reaction gas onto the absorption layer at a second temperature; and
purging a remaining second reaction gas from the substrate.

18-21. (canceled)

22. The method of claim 17, further comprising:
forming a metal oxynitride layer on the substrate by providing a third reaction gas onto the metal oxide layer;
treating the metal oxynitride layer with a plasma; and
purging a remaining third reaction gas from the substrate.

23-24. (canceled)

25. The method of claim 17, further comprising:
forming a cylindrical lower electrode on the substrate prior to forming the metal oxide layer; and
forming an upper electrode on the metal oxide layer.

26. The method of claim 17, further comprising:
forming an insulation layer on the substrate prior to forming the metal oxide film;
forming a floating gate having a U shape on the insulation layer before forming the metal oxide layer; and
forming a control gate on the metal oxide layer.

27-36. (canceled)
